(19) United States
(12) Patent Application Publication
(10) Pub. No.: US 2007/0134902 A1
(43) Pub. Date: Jun. 14, 2007

(54) Patterning of Substrates with Metal-Containing Particles

(75) Inventors: Massimo Bertino, Rolla, MO (US); Nicholas Leventis, Rolla, MO (US); Akira Tokuhiro, Manhattan, KS (US); Guohui Zhang, St. Louis, MO (US)

Correspondence Address: POLSINELLI SHALTON FLANIGAN SUELTHAUS PC, 700 W. 47TH STREET, SUITE 1000, KANSAS CITY, MO, 64112-1802, US

(73) Assignee: THE CURATORS OF THE UNIVERSITY OF MISSOURI, Rolla, MO (US)

(21) Appl. No.: 11/608,496

(22) Filed: Dec. 8, 2006

Related U.S. Application Data
(60) Provisional application No. 60/749,421, filed on Dec. 12, 2005.

(51) Int. Cl. H01L 21/44

(52) U.S. Cl. 438/610

(57) ABSTRACT

The present invention relates to process for patterning metal-containing particles on or in a substrate. The present invention also relates to a non-etched substrate having metal-containing particles patterned thereon.

### CROSS-REFERENCE TO RELATED APPLICATION

This application claims priority from Provisional Application Ser. No. 60/749,421 filed on Dec. 12, 2005, which is hereby incorporated by reference in its entirety.

### FIELD OF THE INVENTION

The present invention relates to processes for patterning substrates with metal-containing particles. The present invention also relates to a non-etched substrate having metal-containing particles selectively patterned thereon.

### BACKGROUND OF THE INVENTION

Patterning of substrates with metallic particles, and in particular, nanoparticles, is becoming increasingly important for optical and electronic applications, and for data storage and encryption. Quantum dot based composite substrates are particularly attractive, since they can be used for a variety of applications. Quantum dot lasers, for example, have been fabricated by embedding quantum dots in titania sol-gel matrix. PbS and CdS nanoparticles embedded in silica gels are being considered for waveguide and non-linear optics applications; and composites of silica gel and cytochrome-tagged Au nanoparticles are likely to have implications in biotechnology. In addition, sol-gel matrices patterned with regularly spaced arrays of nanoparticles are used in the production of optoelectronic components such as diffraction gratings, photonic crystals, and optical memories.

While substrates patterned with quantum dots are highly beneficial, the cost of producing the substrate composite has prevented their widespread application. Currently, substrates are patterned with nanoparticles either by photoreduction, or by using a multiphoton ionization technique that includes impregnation of the substrate with a solution of metal ions followed by photo reduction. These techniques, however, only produce substrates having silver noble metal particles. Composites made of sol gel materials and quantum dots are currently produced by either adding preformed semiconductor quantum dots during gelification, or by calcination of the substrate precursor once the gels have been dried. Undesirably, the substrate composites produced by these methods can only be patterned by etching, adding significant cost to the production of the composite.

A need in the art exists for a process that selectively patterns metal-containing particles on or in a substrate without the use of etching to form the pattern.

### SUMMARY OF THE INVENTION

One aspect of the present invention provides a process for forming a metal-containing nanoparticle on or in a substrate. The process comprises contacting the substrate with a solution to form a substrate solution mixture and applying a directional radiation source to the substrate solution mixture. The solution comprises a metallic agent and a second agent. The directional radiation source causes the second agent to dissociate into at least two particles initiating a reaction between the metallic agent and the dissociated second agent such that the metallic agent deposits on or in the substrate forming a metal-containing nanoparticle.

Another aspect of the invention provides a non-etched, porous substrate, the substrate having selectively patterned metal-containing nanoparticles deposited on or in the substrate. The metal-containing nanoparticles comprise a metal ion selected from the group of consisting of cadmium, mercury, copper, palladium, platinum, lead, and zinc.

Yet another aspect of the invention provides a non-etched, planar substrate. The planar substrate has selectively patterned metal-containing nanoparticles deposited on the substrate's surface.

Other aspects and features of the invention will be in part apparent and in part pointed out hereinafter.

### BRIEF DESCRIPTION OF THE DRAWINGS

FIG. 1A depicts a schematic representation of a directional radiating arrangement employed to pattern a porous substrate.

FIG. 1B depicts a schematic representation of a directional radiating arrangement employed to pattern a planar substrate.

FIG. 2 depicts an optical microscope image of CdS nanoparticles on the surface of a silica hydrogel using IR radiation. The single-headed arrow shows the direction of incident light.

FIG. 3A depicts a TEM micrograph showing CdS nanoparticles as dark spots embedded in a silica hydrogel formed through IR radiation. The sample was illuminated with IR radiation. The scale bar represents 50 nm.

FIG. 3B depicts a size distribution histogram obtained by measuring CdS nanoparticles from FIG. 3A.

FIG. 4 depicts another optical microscope image of CdS nanoparticles on the surface of a silica hydrogel using UV radiation. Samples were illuminated with the 351.1 nm line of a continuous wave Ar ion laser. The laser power at the sample was 50 mW, and exposures were between 5 and 10 minutes.

FIG. 5 depicts an optical microscope image of CdS nanoparticles on a glass slide using UV radiation. Samples were illuminated with the 351.1 nm line of a continuous wave Ar ion laser. The laser power at the sample was 50 mW, and exposures were between 5 and 10 minutes.

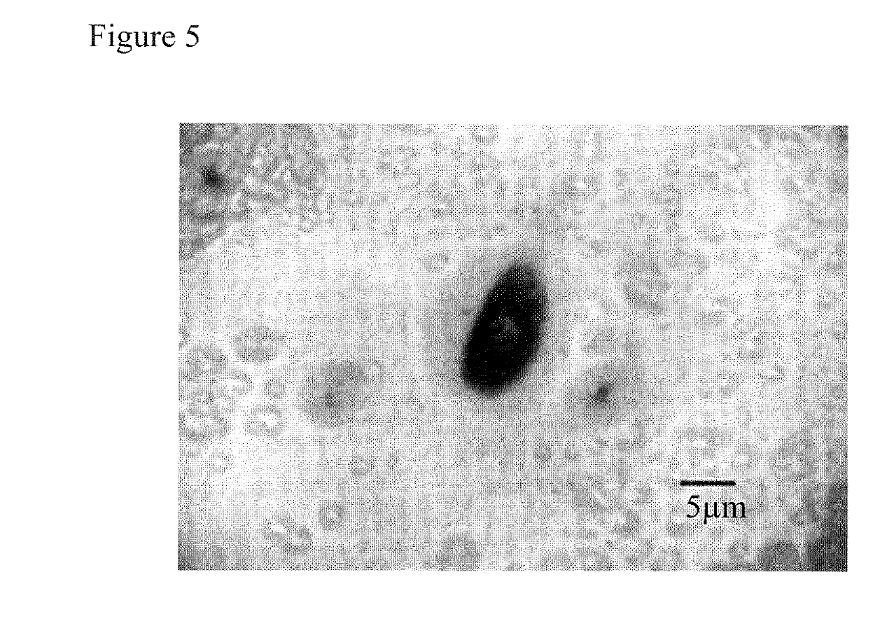

FIG. 6 depicts the optical absorption of an aqueous solution with a CdSO₄ concentration of 0.1 M, a 2-mercaptoethanol concentration of 1 M, and an NH₄OH concentration of 4 M, diluted 800 times. The solutions were illuminated with a high pressure, 100 W Hg lamp for the indicated times.

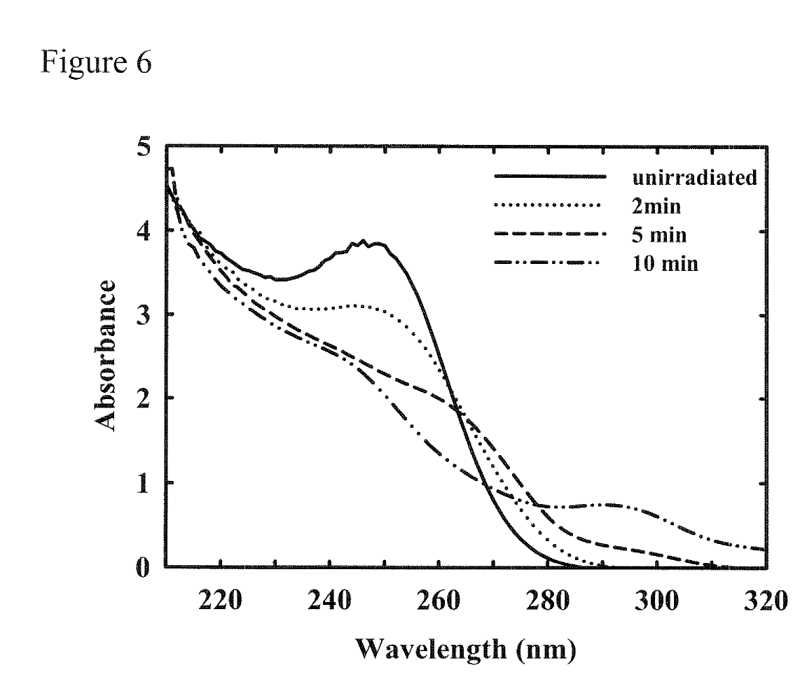

FIG. 7 depicts X-ray diffraction of precipitates formed after exposure of CdSO₄, having a concentration of 0.005 M, and 2-mercaptoethanol, having a concentration of 7 M, solution to ultraviolet light for one hour. A Debye-Scherrer analysis indicated a CdS nanoparticle mean particle size of 1.4 nm. The vertical lines indicate the position of the reflections of bulk cubic CdS, and their length indicates the relative intensity.

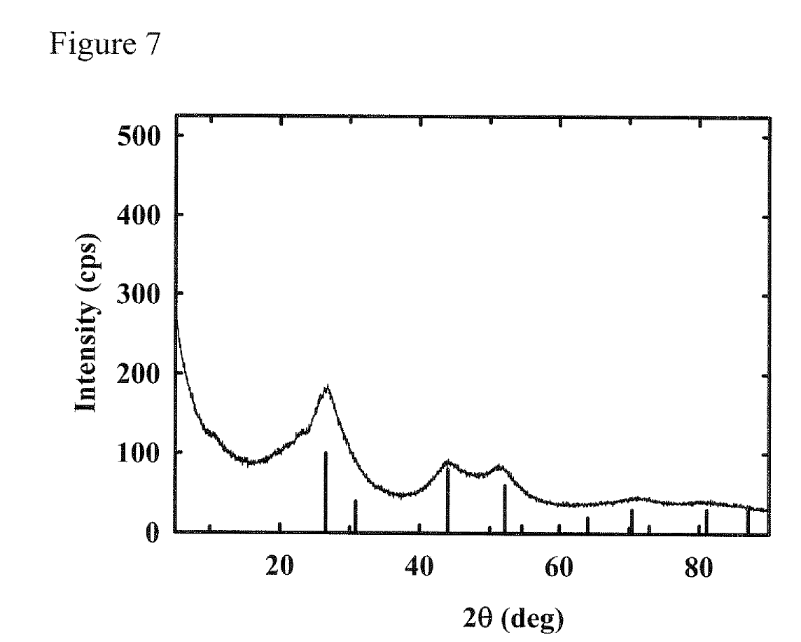

FIG. 8A depicts a TEM micrograph showing CdS nanoparticles as dark spots embedded in a silica matrix. The scale bar represents 100 nm. The inset image is an HRTEM image of a 6 nm diameter CdS nanoparticle. The scale bar within the inset image represents 1 nm. The precursor solution had a CdSO₄ concentration of 0.005 M and a RSH concentration of 7 M. The sample was illuminated for 30 minutes with a high pressure, 100 W Hg lamp.

FIG. 8B depicts a size distribution histogram obtained by measuring about 120 nanoparticles from FIG. 8A.

FIG. 9 depicts the absorption spectra of hydrogels patterned with CdS nanoparticles using UV radiation. The curves correspond to an exposure time of 30, 60, and 90 min, respectively. The precursor solution had a CdSO₄ concentration of 0.005 M and a RSH concentration of 7 M. The samples were illuminated with a 100 W Hg lamp.

FIG. 10 depicts the photoluminescence of hydrogels patterned with CdS nanoparticles using UV radiation. The curves correspond to an exposure time of 30, 60, and 90 min, respectively. The precursor solution had a CdSO₄ concentration of 0.005 M and a RSH concentration of 7 M. The samples were illuminated with a 100 W Hg lamp. The excitation wavelength was 350 nm.

FIG. 11 depicts the Raman spectra of hydrogels patterned with CdS nanoparticles using UV radiation. The precursor solution had a CdSO₄ concentration of 0.005 M and a RSH concentration of 7 M. The samples were illuminated for 30 minutes with a 100 W Hg lamp.

FIG. 12A depicts the optical absorption of a microscope glass slide patterned with CdS nanoparticles. The precursor solution had a CdSO₄ concentration of 0.1 M and a RSH concentration of 1 M. The samples were illuminated for 60 minutes with a 100 W Hg lamp.

FIG. 12B depicts the photoluminescence emission spectra of a microscope glass slide patterned with CdS nanoparticles, excited at 350 nm. The precursor solution had a CdSO₄ concentration of 0.1 M and a RSH concentration of 1 M. The samples were illuminated for 60 minutes with a 100 W Hg lamp.

FIG. 13 depicts the XPS spectra of CdS nanoparticles photolithographed on Si wafers. A) Cd 3d. B) S 2p. The binding energies of Cd_{3d5/2} (405.5 eV) and Cd_{3d3/2} (412.2 eV) nearly coincided with those previously reported for small CdS nanoparticles capped with mercaptoethanol by M. Kundu, A. A. Khosravi, S. K. Kulkarni and P. Singh, J. Mater. Sci., 1997, 32, 245 and R. B. Khomane, A. Manna, A. B. Mandale and B. D. Kulkarni, Langmuir, 2002, 18, 9237. The precursor solution had a CdSO₄ concentration of 0.1 M and a RSH concentration of 1 M. The samples were illuminated for 60 minutes with a 100 W Hg lamp.

FIG. 14 depicts CdS nanoparticles photolithographed in the bulk of a silica hydrogel using IR light. The laser power on the silica hydrogel was 23 W. The dimensions of the lines are i) 2.3 mm×0.3 mm, exposure time was 1 minute and ii) 3.3 mm×0.4 mm, exposure time was 2 minutes.

FIG. 15 depicts a TEM micrograph showing CdS nanoparticles as dark spots embedded in a silica hydrogel. The scale bar represents 100 nm. The inset image is a HRTEM image of a 5 nm diameter CdS nanoparticle. The precursor solution had a CdNO₃ concentration of 0.5 mol/l, an NH₄OH concentration of 2 mol/l, and a thiourea concentration of 0.5 mol/l. Gels were illuminated for 5 minutes with a power of 1.8 W.

FIG. 16 depicts the absorption spectra of hydrogels patterned with CdS nanoparticles. The precursor solution had a CdNO₃ concentration of 0.5 mol/l, an NH₄OH concentration of 2 mol/l, a thiourea concentration of 0.5 mol/l, and either of the capping agents indicated in the caption with a concentration of 0.1 mol/l. Gels were illuminated for 5 minutes at a power of 1.8 W.

FIG. 17 depicts the photoluminescence of hydrogels patterned with CdS nanoparticles using IR photolithography. The precursor solution had a CdNO₃ concentration of 0.5 mol/l, an NH₄OH concentration of 2 mol/l, a thiourea concentration of 0.5 mol/l, and the indicated capping agents in a concentration of 0.1 mol/l. Gels were illuminated for 5 minutes at a power of 1.8 W. Excitation wavelength was 350 nm.

FIG. 18 depicts the raman spectra of hydrogels patterned with CdS nanoparticles using IR light. The precursor solution had a CdNO₃ concentration of 0.5 mol/l, an NH₄OH concentration of 2 mol/l, and a thiourea concentration of 0.5 mol/l. Gels were illuminated for 5 minutes at a power of 1.8 W.

FIG. 19 depicts CdS nanoparticles photolithographed on a glass slide using IR light. Dimensions of the nanoparticles are 0.6 mm×0.8 mm. The precursor solution had a CdNO₃ concentration of 0.5 mol/l, an NH₄OH concentration of 2 mol/l, a thiourea concentration of 0.5 mol/l, and 2-mercaptoethanol concentration of 0.1 mol/l. The laser power on the silica hydrogel was 23 W.

FIG. 20 depicts the optical absorption spectra of microscope glass slides patterned with CdS nanoparticles. The precursor solution had a CdNO₃ concentration of 0.5 mol/l, an NH₄OH concentration of 2 mol/l, a thiourea concentration of 0.5 mol/l, and the 2-mercaptoethanol concentration reported in the caption. Slides were illuminated for 3 minutes at a laser power of 1.8 W.

FIG. 21 depicts the luminescence of microscope glass slides patterned with CdS nanoparticles. The precursor solution had a CdNO₃ concentration of 0.5 mol/l, an NH₄OH concentration of 2 mol/l, a thiourea concentration of 0.5 mol/l, and the 2-mercaptoethanol concentration reported in the caption. Slides were illuminated for 3 minutes at a laser power of 1.8 W. The excitation wavelength was 350 nm.

FIG. 22 depicts a XPS spectra of CdS nanoparticles photolithographed on Si wafers. a) Cd 3d. b) S 2p. The precursor solution had a CdNO₃ concentration of 0.5 mol/l, an NH₄OH concentration of 2 mol/l, and a thiourea concentration of 0.5 mol/l. Wafers were illuminated for 3 minutes at a power of 1.8 W.

### DETAILED DESCRIPTION OF THE INVENTION

The present invention provides processes for patternining substrates with metal-containing particles. In particular, a non-etching process for patterning substrates with metal-containing particles has been discovered. The process allows the metal-containing particles to be selectively formed on the substrate. The process of the invention generally includes contacting the substrate with a solution comprising a metallic agent and a second agent and applying a directional radiation source. Generally speaking, the pattern of the metal-containing particles on the substrate may be controlled by the location at which the directional radiation source contacts the substrate.

I. Substrate

One aspect of the invention provides process for selectively patterning a metal-containing particle on or in a substrate. In a preferred embodiment, the particle is typically a nanoparticle. Generally, the substrate utilized in the process of the invention may be a porous matrix or planar surface and as will be appreciated by a skilled artisan, may be made of a variety of materials suitable for the intended use of the substrate.

In one embodiment, the substrate is a porous matrix. A porous matrix, as used herein, is typically a substrate having an average pore diameter of from about 1 nm to 100 μm. As will be appreciated, however, the pore size can and will vary and the present invention includes substrates having average pore diameters outside of the ranges stated herein. A variety of porous matrices are suitable for use in the present invention. For example, the substrate may be a hydrogel, a zeolite, an aerogel, a xerogel, an ambigel, a ceramic, or a polymer. In an exemplary embodiment, the porous matrix is a silica hydrogel or aerogel. The silica hydrogel or aerogel may be prepared by a variety of methods generally known in the art, such as by conventional base-catalyzed route as detailed in the examples, by a conventional acid-catalyzed route or it may be commercially purchased.

In another embodiment, the porous matrix may be a polymer, a copolymer, a terpolymer, or mixtures thereof. A variety of polymers are suitable for use in the process of the invention. The polymer may be derivatized with a halogen or other functional groups such as phosphates, carboxylates, silanes, siloxanes, sulfides, including POOH, POSH, PSSH, OH, SO₃H, SO₃R, SO₄R, COOH, NH₂, NHR, NR₂, CONH₂, NH—NH₂, and others, where R may comprise any of aryl, alkyl, alkylene, siloxane, silane, ether, polyether, thioether, silylene, and silazane. Examples of other polymers are homopolymers or copolymers of vinyl, acrylate, methacrylate, vinyl aromatic, vinyl esters, alpha beta unsaturated acid esters, unsaturated carboxylic acid esters, vinyl chloride, vinylidene chloride, and diene monomers. Further examples of polymers include a hydrogen-containing fluoroelastomer, a hydrogen-containing perfluoroelastomer, a hydrogen containing fluoroplastic, a perfluorothermoplastic, at least two different fluoropolymers, or a cross-linked halogenated polymer.

Other suitable polymers include poly[2,2-bistrifluoromethyl-4,5-difluoro-1,3-dioxole-co-tetrafluoroethylene], poly[2,2-bisperfluoroal-kyl-4,5-difluoro-1,3-dioxole-co-tetrafluoroethylene], poly[2,3-(perfluoroalkenyl)perfluorotetrahydrofuran], poly[2,2,4-trifluoro-5-trifluoromethoxy-1,3-dioxole-co-tetrafluoroethylen-e], poly(pentafluorostyrene), fluorinated polyimide, fluorinated polymethylmethacrylate, polyfluoroacrylates, polyfluorostyrene, fluorinated polycarbonates, fluorinated poly (N-vinylcarbazole), fluorinated acrylonitrile-styrene copolymer, fluorinated Nafion®, fluorinated poly(phenylenevinylene), perfluoro-polycyclic polymers, polymers of fluorinated cyclic olefins, copolymers of fluorinated cyclic olefins, polymethylmethacrylates, polystyrenes, polycarbonates, polyimides, epoxy resins, cyclic olefin copolymers, cyclic olefin polymers, acrylate polymers, PET, polyphenylene vinylene, polyether ether ketone, poly (N-vinylcarbazole), acrylonitrile-styrene copolymer, poly(phenylenevinylene), poly(vinylalcohol), poly(vinylpyrrolidone), or polymide.

In an exemplary embodiment, the porous substrate is made of a silicon containing material. Other suitable substrates include aluminum oxide, gallium nitride, gallium arsenide, indium tin oxide, titanium oxide, lead oxide, lead sulfide, lead selenide, and lead telluride. In another embodiment, the substrate may be made of a material selected from the group consisting of a transition metal oxide, a lanthanide oxide, a transition metal chalcogenide, a transition metal chalcogenide alloy, a lanthanide chalcogenide, and mixtures thereof.

Alternatively, the substrate may be a planar substrate. A planar substrate, as used herein, either has no pores or has a pore size of less than 1 nm. In one embodiment, the planar substrate may be selected from the group consisting of a glass, a silicon wafer, and a quartz.

II. Solution

In the process of the invention, the substrate is contacted with a solution to form a substrate solution mixture. The solution generally includes a metallic agent and a second agent, which are described in more detail below. The solution may be an aqueous solution. Alternatively, the solution may be an organic solution.

A. Metallic Agent

Generally, the metallic agent may be one that reacts with the second agent to yield a metal-containing nanoparticle on or in a substrate upon the application of the directional radiation source. The metallic agent, for example, may be a metal ion, a metal complex, and an organometallic compound.

In one embodiment, the metallic agent is a metal ion. Suitable metal ions include a transition metal, a rare-earth metal, a group 13 element, and a group 14 element. The metal ion may also be selected from the group consisting of silver, gold, cadmium, mercury, palladium, platinum, lead, zinc, iron, nickel, cobalt, tungsten, niobium, indium, copper, tantalum, yttrium, scandium, lanthanum, cerium, praseodymium, neodymium, promethium, samarium, europium, gadolinium, terbium, dysprosium, holmium, erbium, thulium, ytterbium, and lutetium.

In another embodiment, the metallic agent is a metal complex or chelate. Suitable metal complexes may be selected from the group consisting of a transition metal and ammonia, a transition metal and an organic molecule containing amino groups, and a transition metal and any molecule containing a sulfur atom. In a further embodiment, the metallic agent is a metal complex selected from the group consisting of silver nitrate, cadmium nitrate, cadmium sulfate, cadmium thiolate and selenate, lead thiolate and selenate, zinc thiolate and selenate, silver sulfate, silver perchlorate, cadmium perchlorate, lead perchlorate, lead acetate, cadmium acetate, and silver acetate. In another exemplary embodiment, the metallic agent is a metal complex selected from the group consisting of silver nitrate, cadmium nitrate, cadmium sulfate, silver sulfate, lead nitrate, and zinc nitrate.

In another embodiment, the metallic agent is an organometallic compound. Suitable organometallic compounds may be selected from the group consisting of carbonyls, acetylacetones, thiolates, crown ethers, and amines.

B. Second Agent

Generally, as detailed above, the second agent is selected so that it reacts with the metallic agent to yield a metal-containing particle on or in a substrate when the directional radiation source is applied. Those skilled in the art will appreciate that the second agent can and will vary depending on the type of metallic agent.

In one embodiment, the second agent is a reducing agent. The strength of the reducing agent selected will depend upon the metallic agent. For example, when the metallic agent is relatively difficult to reduce, such as iron, nickel, or cobalt, a relatively strong reducing agent, such as hydrazine is utilized. In contrast, when the metallic agent is relatively easy to reduce, such as silver or gold, a weaker reducing agent may be utilized, such as formaldehyde. Suitable reducing agents include formaldehyde, hydrazine, sodium borohydride, sodium alanate, potassium borohydride, 2-propanol, mercaptoethanol, ferrous compounds, lithium aluminum hydride, potassium ferricyanide hydrogen, sodium amalgam, stannous compounds, zinc-mercury amalgam, diisobutylaluminum hydride, oxalic acid, and citrate. In an exemplary embodiment, the reducing agent is selected from the group consisting of formaldehyde, hydrazine, sodium borohydride, and ferrous compounds.

In yet another embodiment, the second agent is a sulfur-containing agent. Suitable sulfur-containing agents include 2-mercaptoethanol, thioglycerol, thiourea, thioacetamide, octanethiol, mercaptoundecanol, mercaptoundecanoic acid, and thioglycolic acid. In an exemplary embodiment, the sulfur-containing agent is selected from the group consisting of 2-mercaptoethanol, thioglycerol, thiourea, thioacetamide, and mercaptoundecanol.

Generally, the solution of the invention may include a variety of metallic agents and a second agents. In one aspect of the invention, the solution may include more than one metallic agent in combination with one or more second agents. In another aspect of the invention, the solution may include one metallic agent in combination with more than one second agent. In yet another aspect of the invention, the solution may further include a base, such as ammonium hydroxide.

The solution may further include a capping agent. A capping agent typically limits the size of the metal-containing nanoparticle by forming chelates within the solution that do not dissociate when irradiated with the directional radiation source. In one embodiment, the capping agent may be used to limit the size of the metal-containing nanoparticle to a size smaller than the pore of the matrix. In another embodiment, the capping source may be used to limit the size of the metal-containing nanoparticle in a planar substrate. Generally, several capping agents that form a chelate with the metallic agent or second agent may be used in accordance with the invention. In one exemplary embodiment, the capping agent may be selected from the group consisting of hexametaphosphate, 2-mercaptoethanol, and thioglycerol.

As will be appreciated by the skilled artisan, and as illustrated in the examples herein, the reaction parameters of the process of the present invention can and will vary. In one embodiment, by way of non-limiting example, a porous matrix is contacted with a solution comprising a metallic agent and a second agent at a temperature of from about 2° C. to about 12° C. In another embodiment, the porous matrix is contacted with a solution comprising a metallic agent and a second agent at a temperature of from about 4° C. to about 8° C. Typically, the porous matrix is contacted with a solution for from about 1 minute to about 2 hours. In another embodiment, the porous matrix is contacted with the solution for from about 5 minutes to about 2 hours. Generally, the porous matrix is contacted with the solution at a temperature of from about 2° C. to about 12° C., for from about 5 minutes to about 2 hours, at a pH of from about 7 to about 8.

In another embodiment, by way of non-limiting example, a planar matrix may be contacted with a solution comprising a metallic agent and a second agent. In one exemplary embodiment, the planar substrate is coated with the solution. The coating of the planar substrate can be carried out by commonly used coating processes, e.g., drop casting, spin coating, dip coating, spray coating, flow coating, screen printing, etc., but is not limited to these processes. In one embodiment, planar substrate is spin coated with a solution.

Those skilled in the art will appreciate that the concentration of the solution will vary depending on the type of metallic agent and second agent used. In one embodiment, the solution comprises a metallic agent concentration of from about 0.005 M to about 1 M, and a second agent concentration of from about 0.1 M to about 7 M. In another embodiment, the solution comprises a metallic agent concentration of from about 0.005 M to about 2 M, a second agent concentration of from about 0.1 M to about 7 M, and a base concentration of from about 1 M to about 4 M. In yet another embodiment, the solution comprises a metallic agent concentration of from about 0.005 M to about 2 M, a second agent concentration of from about 0.1 M to about 7 M, a base concentration of from about 1 M to about 4 M, and a capping agent concentration of less than about 0.1 M. In a further embodiment, the solution comprises a metallic agent concentration of from about 0.2 M to about 1 M, and a reducing agent concentration of from about 0.2 M to about 1 M. In yet a further embodiment, the solution comprises a metallic agent concentration of from about 0.005 M to about 1 M, and a sulfur-containing agent concentration of from about 1 M to about 7 M. In another embodiment, the solution comprises a metallic agent concentration of from about 0.005 M to about 1 M, a sulfur-containing agent concentration of from about 1 M to about 7 M, and a base concentration of from about 1 M to 3 M. In another embodiment, the solution comprises a metallic agent concentration of from about 0.005 M to about 1 M, a sulfur-containing agent concentration of from about 1 M to about 7 M, a base concentration of from about 1 M to 3 M, and a capping agent concentration of less than about 0.1 M.

III. Directional Radiation Source

After the substrate is contacted with the solution forming a substrate solution mixture, a directional radiation source is applied to the substrate solution mixture. Generally, the directional radiation source irradiates the solution mixture initiating a reaction between the metallic agent and the second agent. The direct radiation, without being bound to any particular theory, typically causes the second agent to dissociate into at least two particles initiating a reaction between the metallic agent and the dissociated second agent such that a metal-containing particle deposits on or in the substrate. The two particles may, for example, each be a radical, an atom, a molecule, an ion, or an electron. In one embodiment, the two particles are the same, for example, each particle is an atom. In another embodiment, the two particles are different, for example, one particle is an atom and another particle is a molecule. In particular, the process of the invention provides a process for selectively patterning a substrate with metal-containing particles, and in particular, a nanoparticle.

Selectively patterned, as used herein, means that the physical location of a metal-containing particle formed on or in the substrate is controlled, or predetermined, by the location at which the directional radiation source contacts the substrate. As such, the process of the invention allows for the formation of a metal-containing particles at any desired location on or in the substrate. In one exemplary embodiment, the directional radiation source is directed at a desired location on the surface of the substrate and a metal-containing particle deposits at that location on the surface of the substrate. In another embodiment, the directional radiation source is directed below the surface of the substrate and a metal-containing nanoparticle deposits at that location inside the substrate.

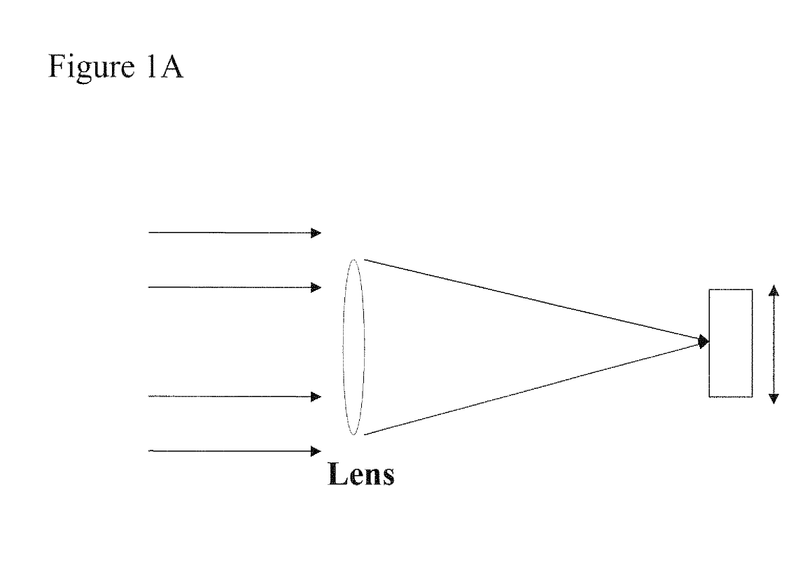

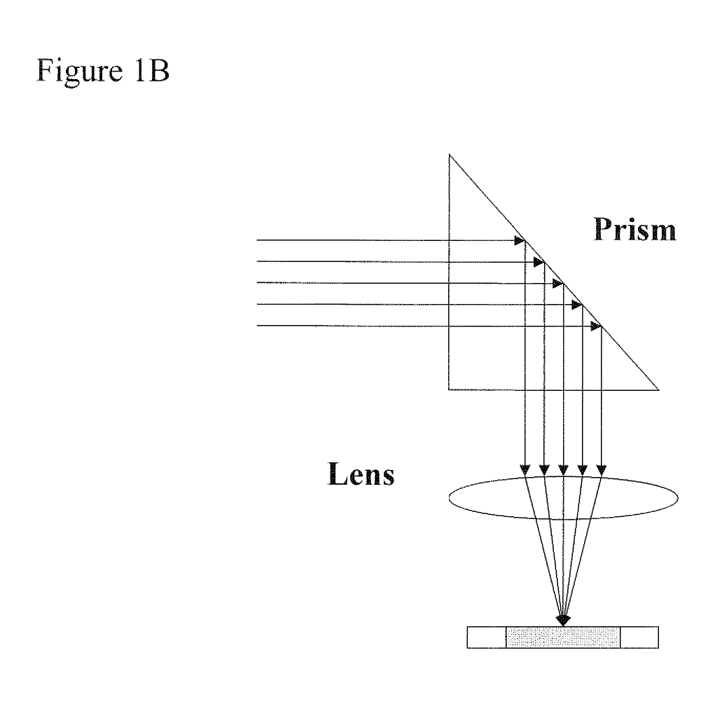

FIGS. 1A and 1B depict a non limiting schematic representation showing one means by which the directional radiation source is used to pattern a porous substrate and a planar substrate respectively. Generally, the directional radiation source may be applied to a lens that focuses the radiation source onto a particular location on or in the substrate. The distance along the optical axis from the lens to the location on the substrate, or focal point, is the focal length. In one embodiment, the directional radiation source is applied onto a prism and lens system that focuses the radiation source onto a particular location of a planar substrate.

A directional radiation source, as used herein, is one or more radiation sources that may accurately direct radiation onto a particular location on or in the substrate. In one embodiment, the directional radiation source is continuous or pulsed. In one embodiment, the directional radiation source is selected from the group consisting of ionizing radiation and non-ionizing radiation. A variety of types of ionizing radiation are suitable for use in the process of the invention. Suitable sources of ionizing radiation include ultraviolet light, gamma rays, X-rays, and electron beams. In an exemplary embodiment, the directional radiation source is ultraviolet light. Alternatively, the directional radiation source may be non-ionizing radiation. Suitable examples of non-ionizing radiation include microwaves, visible light, and infrared light. In an exemplary embodiment, the directional radiation source is infrared light. In a further embodiment, the pulsed radiation source may be applied onto the substrate solution mixture for about 1 fs to about 1 second.

In another embodiment, one or more directional radiation source may be applied onto the substrate at one time. In yet another embodiment, one or more directional radiation sources may be applied parallel to each other onto the substrate. In a further embodiment, a mask or cover may be placed between the parallel directional light sources and the sample such that the particles only form wherein the parallel directional radiation source contacts the substrate. In another embodiment, one or more directional radiation sources intersect on the substrate. In yet another embodiment, one or more directional radiation sources may be applied onto the substrate such that the directional radiation sources interfere on the substrate thereby forming nanoparticles on or in the substrate.

A variety of equipment capable of emitting ionizing or non-ionizing radiation may be used to apply the directional radiation source of the present invention. In one embodiment, an argon ion laser may be used to apply ultraviolet light onto the substrate solution mixture. An argon ion laser may be commercially purchased from, for example, Coherent, Inc. In another embodiment, a mercury arc discharge lamp may be used to apply ultraviolet radiation onto the substrate solution mixture. A mercury lamp may be commercially purchased from, for example, Pasco Scientific. In yet another embodiment, a Nd-YAG laser may be used to apply infrared light onto the substrate solution mixture. In a further embodiment, an IPG Photonics corporation laser of model number YLR-100 may be used to apply infrared light onto the substrate solution mixture. In a further embodiment, an electron beam may be used to apply ionizing radiation onto the substrate mixture.

In the process of the invention, the directional radiation source is generally applied onto the substrate solution mixture at a wavelength sufficient to initiate the reaction between the metallic agent and the second agent. In one embodiment, the directional radiation source is ultraviolet light emitted at a wavelength of from about 160 nm to about 390 nm. In yet another embodiment, ultraviolet light is applied onto the solution mixture for about 1 min to about 60 min. In an exemplary embodiment, ultraviolet light is applied using a high pressure, 100 W mercury arc discharge lamp. In another exemplary embodiment, ultraviolet light is applied at a wavelength of from about 350 nm to about 365 nm by a continuous wave Argon ion laser.

In another embodiment, the directional radiation source is infrared light emitted at a wavelength of from about 800 nm to about 5000 nm. In another embodiment, infrared light is applied onto the solution mixture for from about 1 ms to about 10 min. In an exemplary embodiment, infrared light is applied at a wavelength of about 1040 nm by a continuous wave Nd-YAG laser.

The process of the invention also provides a technique for varying the size of the metal-containing nanoparticle and/or an agglomeration of nanoparticles deposited on or in the substrate by adjusting the distance between the directional radiation source and the substrate. The process also provides a technique for depositing contiguous metal-containing nanoparticles on or in the substrate. In particular, the cluster or agglomeration of a metal-containing nanoparticles may be varied from about 50 nm to about 10 mm by changing the distance between the porous substrate and the focal length.

Alternatively, the process of the present invention also provides a technique for two- and three-dimensional patterning of a substrate. In one embodiment, the metallic nanoparticles are deposited on or in the substrate in a two-dimensional pattern. In another embodiment, the metallic nanoparticles are deposited on or in the substrate in a three-dimensional pattern.

In another embodiment, a plurality of metallic particles, and in particular, nanoparticles, is deposited on or in the substrate. In yet another embodiment, the plurality of metallic nanoparticles deposited on or in the substrate have the same composition, meaning the particles comprise the same metal. In a further embodiment, the plurality of metallic nanoparticles on or in the substrate are of different compositions, meaning the particles comprise at least two different metals. Generally speaking, the density of metallic particles on or in the substrate is from about 0.001% to about 30% by volume. In another embodiment, the density of metallic nanoparticles on or in the substrate is from about 1% to about 6% by volume. The density of particles deposited on or in the substrate, however, can be increased, by repeating the steps of the process of the invention several times, such as by the procedure detailed below.

To increase the density of particles formed on or in the substrate, the following process may be used. The process for forming metallic particles on or in a substrate includes contacting the substrate with a first solution to form a first substrate solution mixture. The first substrate solution mixture including a first metallic agent and a second agent. The process includes applying a directional radiation source onto the first substrate solution mixture, wherein the directional radiation source initiates a reaction between the first metallic agent and the second agent such that a first metallic nanoparticle is formed on or in the substrate. The process further includes contacting the substrate with a second solution to form a second substrate solution mixture. The second substrate solution mixture including a second metallic agent and a third agent. The process also includes applying a directional radiation source onto the second substrate solution mixture, wherein the directional radiation source initiates a reaction between the second metallic agent and the third agent such that a second metallic nanoparticle deposits on or in the substrate. The steps may be repeated the number of times necessary to form the desired density of particles on or in the substrate.

The first and second metallic agent may be selected from any metallic agent in Part II, A of the specification above. In one embodiment, the first metallic agent and the second metallic agent are the same. In another embodiment, the first metallic agent is not the same as the second metallic agent.

The second and third agent may be selected from any second agent in Part II, B of the specification above. In one embodiment, the second agent and the third agent are the same. In another embodiment, the second and third agent are not the same.

After applying the directional radiation source, the process may further include washing the substrate with a cleansing solution to remove any unreacted solution there from. The cleansing solution may be a solution that removes the unreacted solution without removing or altering the metal-containing nanoparticles patterned on the substrate. Suitable cleansing solutions include, for example, water and acetonitrile.

In another embodiment, after washing the substrate with a cleansing solution a second directional radiation source may be applied to the nanoparticles patterned on or in the substrate to remove any defects, or electrons trapped by the defects, on the surface of the nanoparticles. The second directional radiation source may be ionizing radiation. In an exemplary embodiment, the second directional radiation source is ultraviolet radiation. In one embodiment, the second directional radiation source is applied onto the surface of the nanoparticles on or in the substrate for about 24 to 48 hours with a power of about 5 to about 10 Watts.

IV. Metal-Containing Nanoparticles

In accordance with the process of the present invention, a substrate having a metallic particle deposited on or in the substrate's surface is formed. Generally, the size of the metal-containing particle is limited by the diameter of the pore on the porous matrix. The size of the metal-containing particle may additionally be controlled by the addition of a capping agent to the substrate solution mixture. As such, it is contemplated that the metal particle formed may be a variety of sizes, depending upon the pore size of the substrate and whether a capping agent is used. In an exemplary embodiment, a plurality of metal-containing particles with an average diameter in the nanoparticle range is formed by the process of the invention. In one embodiment, the metal-containing nanoparticle deposited on or in a substrate has an average diameter of from about 0.5 nm to about 1000 μm. In another embodiment, the metal-containing nanoparticle deposited on or in the substrate has an average diameter of from about 0.5 nm to about 100 nm. In yet another embodiment, the metal-containing nanoparticle formed on or in the substrate has an average diameter of from about 1 nm to about 10 nm.

Those skilled in the art can and will appreciate, as illustrated in the examples, that the composition of the metal-containing nanoparticle will vary depending on the metallic agent and second agent. For example, if the second agent is a sulfur-containing agent, the metal-containing nanoparticle will be made of a sulfur-containing material. In one exemplary embodiment, the sulfur-containing material is a quantum dot.

A quantum dot, as used herein, is a nanometer-sized semiconducting material that exhibits quantum confinement effects. In particular, when quantum dots are irradiated by light from an excitation source to reach respective energy excited states, they emit energies corresponding to respective energy band gaps. In one embodiment, the quantum dot is made of a material selected from the group consisting of cadmium sulfide, zinc sulfide, lead sulfide, cadmium selenide, cadmium telluride, zinc selenide, zinc telluride, lead selenide, zinc selenide, and mercury telluride.

Alternatively, if the second agent is a reducing agent, the metal-containing nanoparticle will be made of a metal ion selected from the group consisting of silver, gold, cadmium, mercury, palladium, platinum, lead, zinc, iron, nickel, cobalt, tungsten, niobium, indium, copper, tantalum, yttrium, scandium, lanthanum, cerium, praseodymium, neodymium, promethium, samarium, europium, gadolinium, terbium, dysprosium, holmium, erbium, thulium, ytterbium, and lutetium. In an exemplary embodiment, the metal-containing nanoparticle will be made of a metal ion selected from the group consisting of iron, nickel, cobalt, copper, mercury, palladium, platinum, lead, silver, gold, and cadmium.

Another aspect of the invention provides a non-etched, planar substrate having selectively patterned metallic nanoparticles deposited on the substrate's surface. Yet another aspect of the invention provides a non-etched, porous substrate having selectively patterned metallic nanoparticles deposited on or in the substrate. In one embodiment, the metallic nanoparticles deposited on the porous substrate comprise a metal ion selected from the group consisting of cadmium, mercury, copper, palladium, platinum, lead, and zinc.

The substrates of the present invention may be used in a wide variety of applications. Such applications include electrical devices, optical devices, optronic devices, mechanical devices or any combination thereof, for example, optoelectronic devices, or electromechanical devices. A representative examples of devices include quantum dot lasers, quantum computers, waveguide and non-linear optics applications, optoelectronic components such as diffraction gratings, photonic crystals, and optical memories, biological labeling and tracing of cells, electroluminescent diodes, memory applications, actuators for MEMS applications, and production of three-dimensional electronic circuits, among others.

### DEFINITIONS

To facilitate understanding of the invention, a number of terms and abbreviations as used herein are defined below:

The term “directional radiation source” denotes one or more radiation sources that may be precisely directed onto a particular location on or in the substrate.

The term “group 13 elements” denote elements that have three valence electrons and typically assume +3 oxidation state when forming compounds, including boron, aluminum, gallium, indium, and thallium.

The term “group 14 elements” denote elements that have four valence electrons and may adopt various oxidation states from −4 to +4 in compounds, including carbon, silicon, germanium, tin, and lead.

The term “nanoparticle” denotes a particle with dimensions in nanometer size range.

The term “quantum dot” denotes a nanometer-sized semi conducting material that exhibits quantum confinement effects. In particular, when a quantum dot is irradiated by light from an excitation source to reach respective energy excited states, it emits energies corresponding to respective energy band gaps.

The term “rare-earth metal” denotes elements of the lanthanide series including yttrium, scandium, lanthanum, cerium, praseodymium, neodymium, promethium, samarium, europium, gadolinium, terbium, dysprosium, holmium, erbium, thulium, ytterbium, and lutetium.

The term “selectively patterned” denotes that the physical location of a metal-containing nanoparticle deposited on or in the substrate is controlled, or predetermined, by the location at which the directional radiation source contacts the substrate.

The term “substrate” denotes a porous or planar surface, as the terms are used in any embodiment described herein.

The term “transition metal” denotes elements in groups 3 through 12 of the periodic table, including scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, mercury, rutherfordium, dubnium, seaborgium, bohrium, hassium, meitnerium, ununnilium, unununium, and ununbium.

### EXAMPLES

### Example 1

### Ag Nanoparticles in Silica Hydrogel using IR Radiation

Silica hydrogels were prepared via a conventional base-catalyzed route. Silica aerogel composites were prepared by mixing the contents of vial A (4.514 mL of tetramethoxysilane; 3.839 mL of methanol) and of vial B (4.514 mL of methanol; 1.514 mL of water, and 20 μL of concentrated NH₄OH) to form a sol that gels at room temperature in 10-15 min. The gels were left to age at room temperature for approximately 2 days. Aged gels were removed from their molds and soaked in water, ten times, for 12 h each time. The water-washed gels were washed two more times, 12 h each time, with an aqueous solution of AgNO₃, in a concentration of 1 mol/l. The metal-loaded samples were then placed in a refrigerator, and cooled to about 5° C. Pre-cooled formaldehyde was then added to the vials, to reach a formaldehyde concentration of 1 mol/l. The vials were placed again in the refrigerator for about 2 hours, to let the formaldehyde diffuse from the bathing solution into the hydrogels. The bathing solution was then decanted, and the vials hermetically closed to prevent evaporation of the solvent. The vials were then mounted on a translational stage that allowed the gels to move perpendicular to an incident infrared laser beam, as shown on FIG. 1A. The laser employed in our experiments was a continuous wave (CW) Nd-YAG laser, emitting at a wavelength of 1040 nm. The estimated IR power at the sample was 200 mW. Exposure to the IR light heats the hydrogel locally. Once heated, formaldehyde reduces the metal ions to metal atoms, and metal nanoparticles are formed in the region exposed to the IR beam. The heated region becomes visibly darker. After irradiation, the hydrogels were washed many times with cold distilled water to stop the reaction and wash the precursors out of the gel. The pore-filling acetone was replaced in an autoclave with liquid CO₂, and finally the gels were dried supercritically. The resulting materials have density and porosity typical of aerogels, namely, a surface area between 700 and 1000 m²/g, a mean pore size between 7 and 14 nm, and a density below 0.1 g/cm³.

### Example 2

### CdS Nanoparticles in Silica Hydrogel using IR Radiation

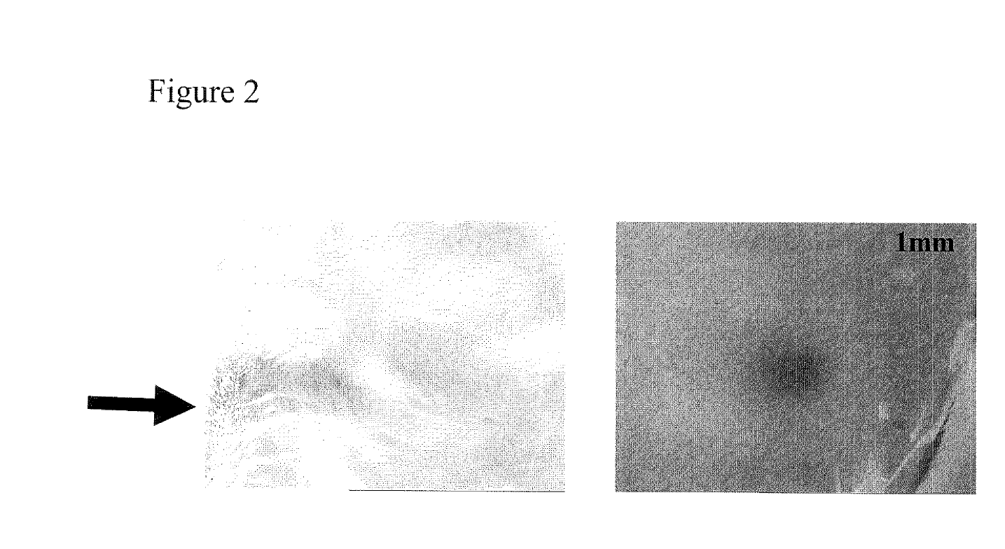

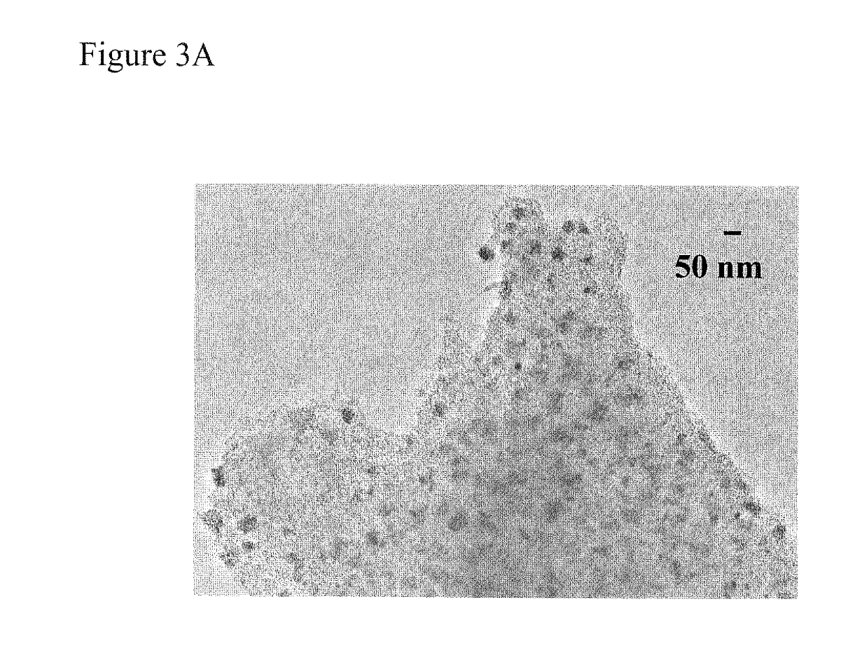

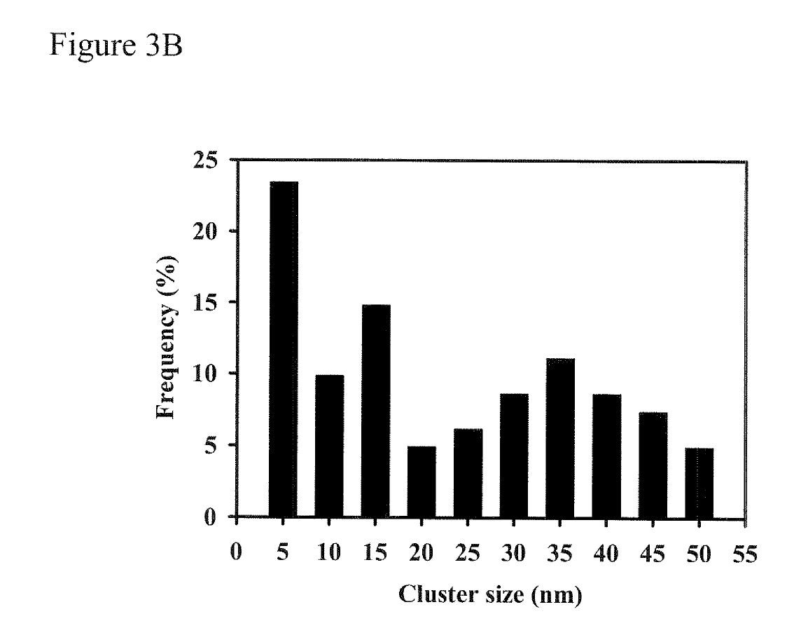

Silica hydrogels were prepared via a conventional base-catalyzed route. Silica aerogel composites were prepared by mixing the contents of vial A (4.514 mL of tetramethoxysilane; 3.839 mL of methanol) and of vial B (4.514 mL of methanol; 1.514 mL of water, and 20 μL of concentrated NH₄OH) to form a sol that gels at room temperature in 10-15 min. The gels were left to age at room temperature for approximately 2 days. Aged gels were removed from their molds and soaked in water, ten times, for 12 h each time. The water-washed gels were washed two more times, 12 h each time, with an aqueous solution of CdNO₃ in a concentration of 1 mol/l, and NH₄OH, in a concentration of 1 mol/l. The hydrogels were left bathing overnight at 5° C. Then, half the volume of the bathing solution was decanted, and replaced by a precooled aqueous solution of thiourea in a concentration of 1 mol/l. The samples were kept refrigerated for at least 2 hours, to let the thiourea diffuse from the bathing solution into the hydrogels. The bathing solution was then decanted, and the vials hermetically closed to prevent evaporation of the solvent. The vials were then mounted on a translational stage that allows the gels to move perpendicular to an incident infrared laser beam, as shown on FIG. 1A. The laser employed in our experiments was a continuous wave (CW) Nd-YAG laser, emitting at a wavelength of 1040 nm. The estimated IR power at the sample was 200 mW. Exposure to the IR light heats the hydrogel locally. The heated region becomes visibly darker as the CdS nanoparticles form, as shown on FIG. 2. A size distribution histogram of the CdS nanoparticles formed is depicted on FIG. 3B.

### Example 3

### CdS Nanoparticle in Silica Hydrogel using UV radiation

Silica hydrogels were prepared following a conventional base-catalyzed route. The hydrogels were then washed several times in methanol and in water. The hydrogels were cut into small cylinders of about 7 mm in diameter, and 5-7 mm in length. The cylinders were then bathed in 20 ml of a solution of CdSO₄ and 2-mercaptoethanol, HOCH₂CH₂SH, for about 2 hours. Several precursor concentrations were tested; the best results were obtained by using a thiol concentration of at least 10 times higher than the metal ion concentration, and by adding NH₄OH to reach a pH of at least 7.5, e.g., [CdSO₄]=0.1 mol·l⁻¹ (M), [HOCH₂CH₂SH]=1 M, [NH₄OH]=4 M. We also worked without adding a base, but with a thiol concentration at least 500 times higher than the metal ion concentration, e.g., [CdSO₄]=0.005 M, and [HOCH₂CH₂SH]=7 M. Exposure times and physical characteristics of the nanoparticles did not depend strongly on the composition of the precursor solution. The hydrogels samples were placed in a glass cuvette filled with the bathing solution for index matching, and were exposed to ultraviolet light. The light source was either a high pressure, 100 W Hg arc discharge lamp, or with the 351.1 nm line excitation wave of a continuous wave Ar ion laser (Coherent Innova). The laser power at the sample was on the order of 50 mW, and the illuminated spots had a diameter between about 3 and 100 μm. To ensure that only the ultraviolet light was initiating the chemical reaction and that visible and infrared light did not play any role, samples were also illuminated with (A) an Ar ion laser emitting only in the visible part of the spectrum with a power of approximately 1 W and (B) a continuous wave infrared laser. CdS did not form in any of these control experiments, confirming that only ultraviolet light induced the reaction of the precursors.

The samples were characterized with transmission electron microscopy (TEM, and high resolution TEM), with UV-Vis optical absorption spectroscopy, photoluminescence spectroscopy, X-ray diffraction (XRD), and X-ray photoelectron spectroscopy (XPS). The apparatus used were a Zeiss EM 109, operated at 80 kV and Phillips 430ST TEM, operated at 300 kV, a CARY 5 UV-Vis-NIR spectrophotometer, a JY-Horiba Fluorolog 3-22 Fluorometer, a Scintag XDS200 diffractometer with a Cu radiation source and a liquid nitrogen cooled Ge detector, and a KRATOS AXIS 165 scanning spectrometer equipped with a 225-W Mg monochromatized X-ray source, producing photons with an average energy of 1253.6 eV respectively.

### Example 4

### CdS Nanoparticle in Silica Hydrogel using UV radiation

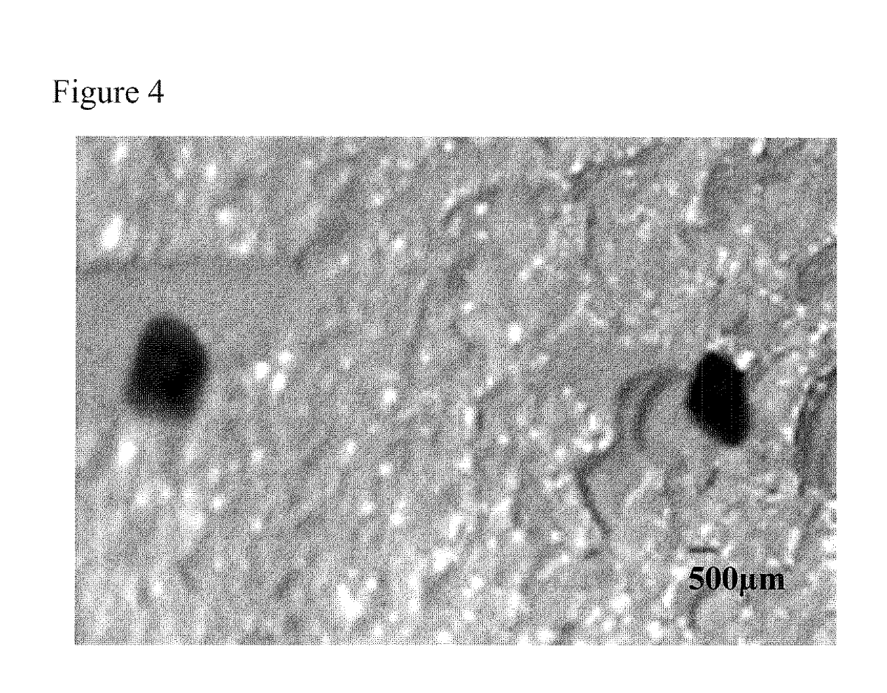

The silica hydrogels of Example 3 after being placed in a solution of CdSO₄[=0.1 mol·l⁻¹ (M), [HOCH₂CH₂SH]=1 M, [NH₄OH]=4 M were exposed to UV light using a Hg lamp and Ar ion laser. Yellowish CdS nanoparticles started forming after illuminating samples with the Hg lamp for 20-30 minutes. Illumination times were of a few minutes when the Ar ion laser was employed. The diameter of the photolithographed CdS nanoparticles could be varied from a few to approximately 100 μm by changing the distance between the sample and the focal length. Typical patterned regions are shown in FIG. 4. Patterns extended into the bulk of hydrogels; the penetration depth could be varied from a few microns to about one millimeter by varying the focal length of the lens.

After irradiation, the samples were washed several times in water to remove unreacted precursors. The size and color of the spots was not altered by washing, indicating that CdS was neither chemically altered nor removed. To help confirm the chemical identity of the nanoparticles in the illuminated regions, some samples were washed with acetonitrile. The color and size of the spots was not altered. This ruled out the presence of unreacted Cd-thiolate precursors, which are highly soluble in acetonitrile. Some samples were also washed in acidic (H₂SO₄) solution. The lithographed regions vanished after a few hours, ruling out the presence of elemental sulfur, and strongly suggesting the presence of CdS nanoparticles.

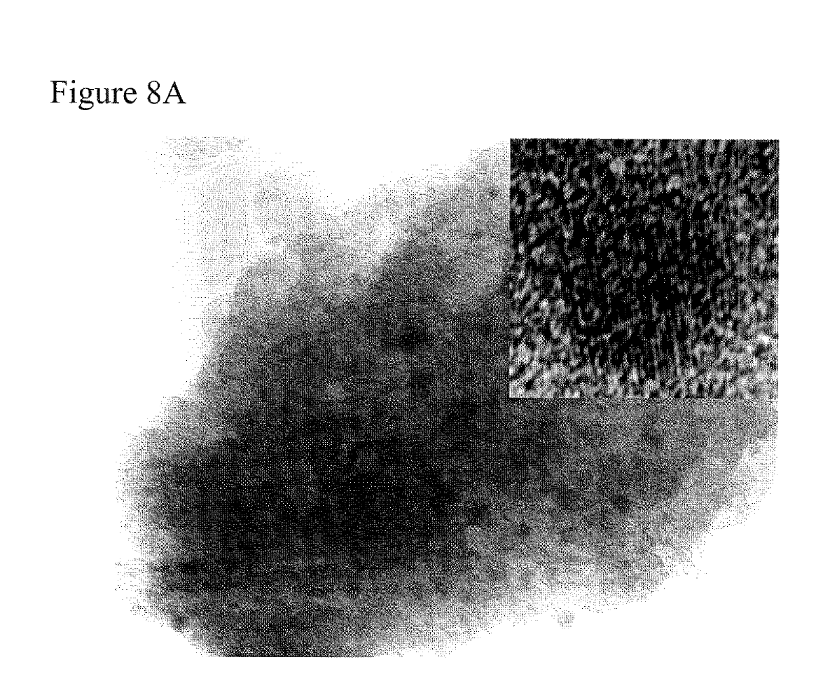

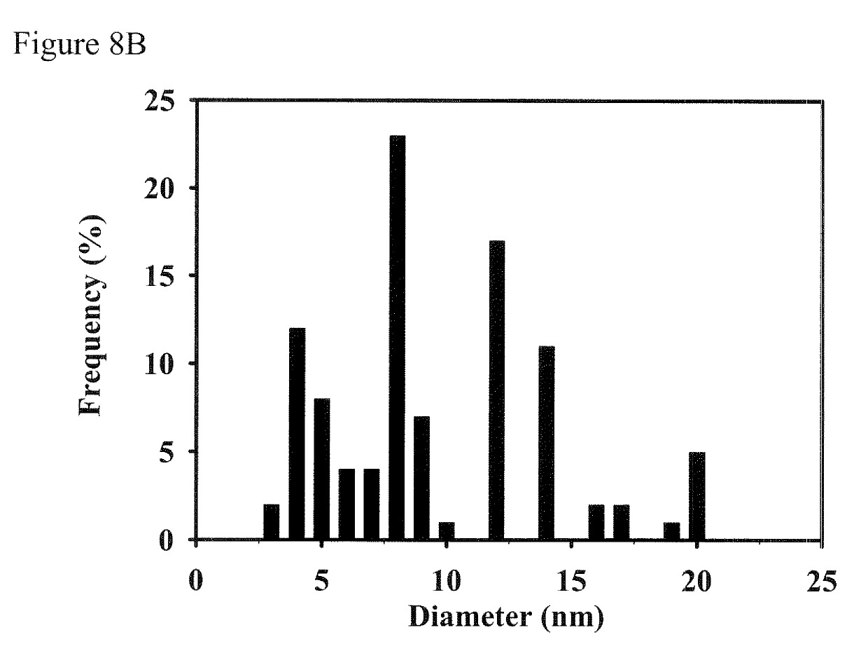

The illuminated regions containing CdS nanoparticles were then carved out of the hydrogel and crushed in methanol and placed on a lacey carbon copper grid. FIG. 8A shows a typical TEM micrograph. CdS nanoparticles with a diameter in the 15-20 nm range were present in all samples, and appeared as dark spots distributed within the light grey silica hydrogel. High magnification micrographs revealed the presence of a large number of particles in the 2-5 nm size range. A size distribution histogram of the particles is shown in FIG. 8B. The histogram does not account for particles smaller than 3 nm, because these could not be distinguished from the hydrogel itself.

The chemical identity of the samples was further confirmed by absorption, photoluminescence, and Raman spectroscopy.

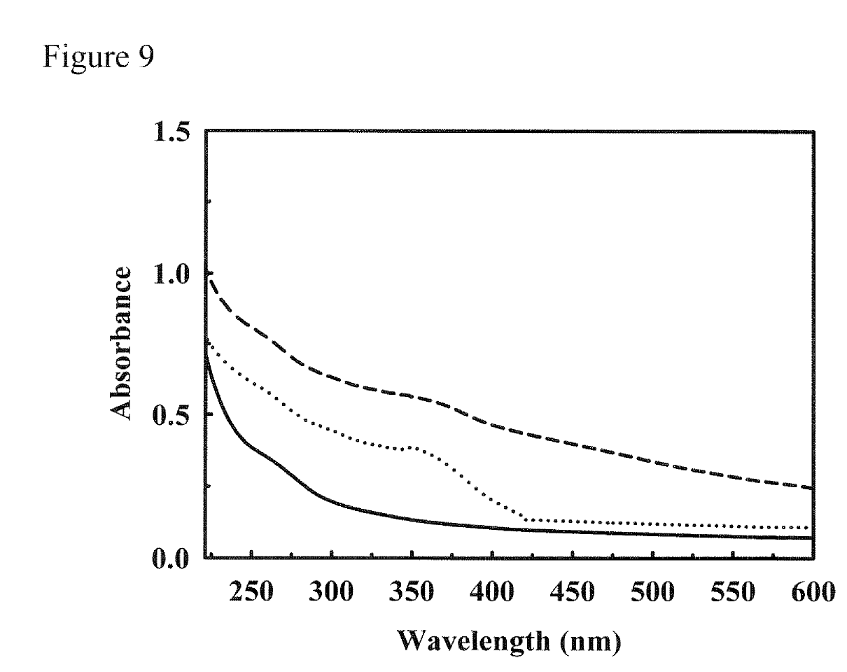

Room temperature absorption spectra taken as a function of exposure time are reported in FIG. 9. The spectra exhibited excitonic shoulders at 270, 360, and respectively 375 nm after an exposure time of 30, 60, and 90 minutes respectively. The position of these shoulders can be reconciled with CdS nanoparticles with a mean diameter of 1.4, 1.7, and 2 nm, respectively.

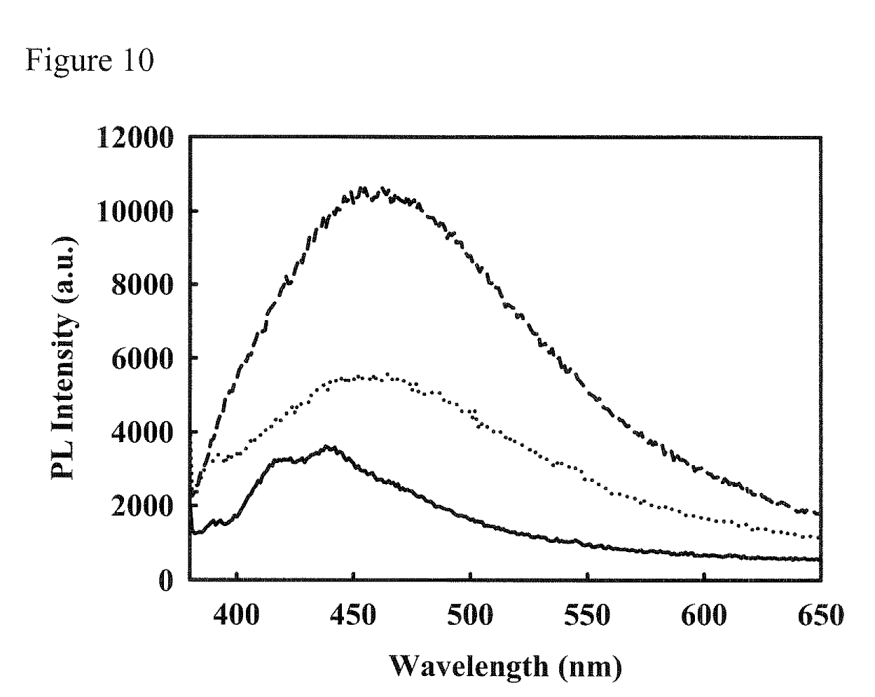

Room temperature photoluminescence (PL) spectra are reported in FIG. 10, and are characterized by broad peaks, indicating that the nanoparticles had a substantial number of defects. Particle size could not be determined from the PL spectra due to the broadness of the peaks; however, some trends could be discerned. Luminescence was in general weak, and increased with irradiation time. Peaks in the 400-450 nm region of the spectrum were often detected in samples irradiated for short times, and were probably due to carbon impurities incorporated in the silica matrix during the gel formation process. The emission profiles tended to shift towards longer wavelengths with increasing irradiation time, in agreement with the trend prevalent in the absorption spectra (see FIG. 9).

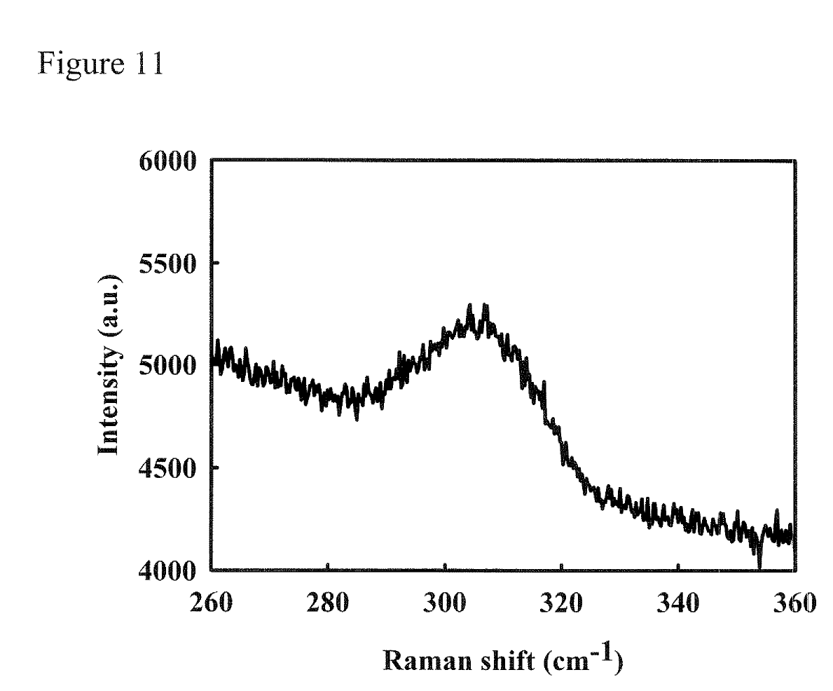

Finally, Raman spectra are shown in FIG. 11, and exhibited a shift at 306 cm⁻¹. This frequency nearly coincides with first-order LO phonon frequency of bulk CdS, and is also in good agreement with previous Raman measurements of CdS/silica composites by A. G. Rolo, L. G. Vieira, M. J. M. Gomes, J. L. Ribeiro, M. S. Belsley, M. P. dos Santos, Thin Solid Films, 1998, 312, 348.

### Example 5

### CdS Nanoparticles on a Planar Substrate using UV Radiation

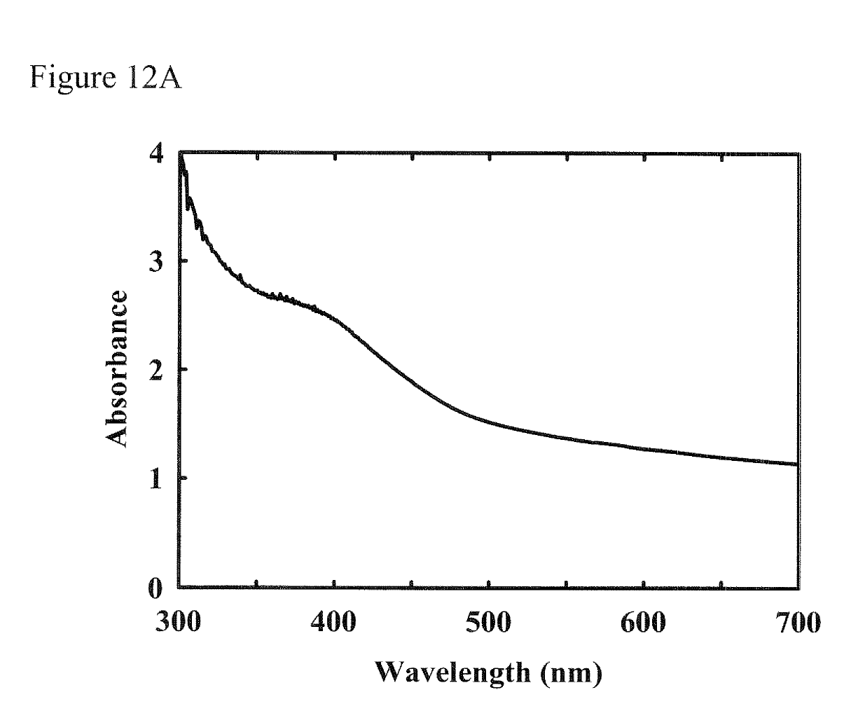

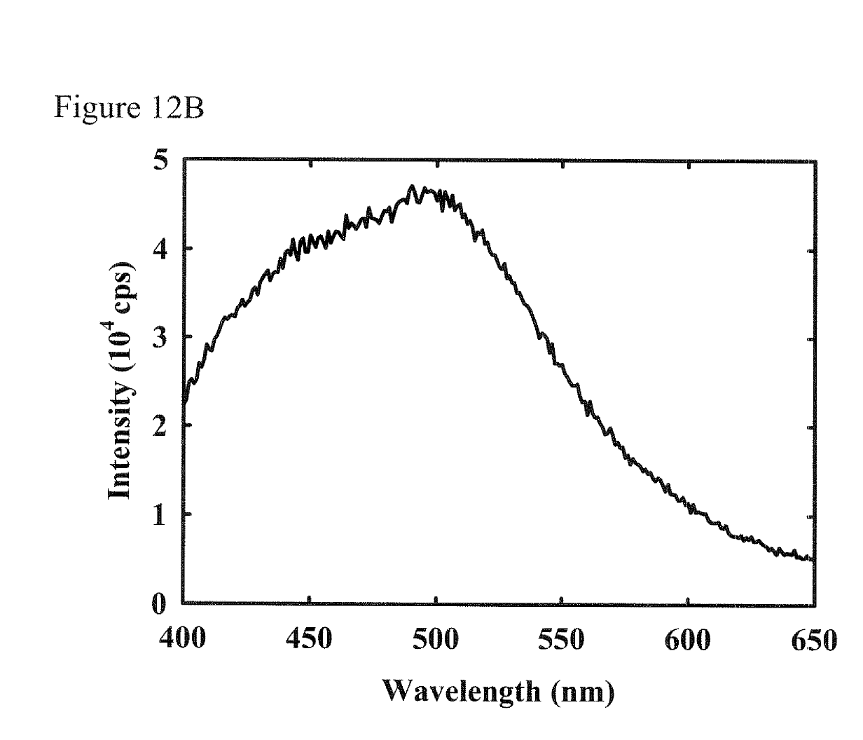

A thin veil of precursor solution including CdSO₄ of a concentration of 0.1 M, 2-mercaptoethanol of a concentration of 1 M, and NH₄OH to maintain a pH of about 11, was spin coated, or simply spread, on glass slides or silicon wafers. The samples were exposed to focused ultraviolet light as shown in FIG. 1B, for 60 minutes with a 100 W high pressure mercury lamp. FIGS. 12A and 12B show the absorption and emission spectra of glass slides patterned with CdS nanoparticles.

Absorption showed an excitonic shoulder around 380 nm. From the position of the excitonic shoulder a mean size of about 2 nm was calculated, close to the mean size of CdS nanoparticles formed in silica gels for comparable irradiation times. Emission was very broad, as in the case of patterned silica hydrogels.

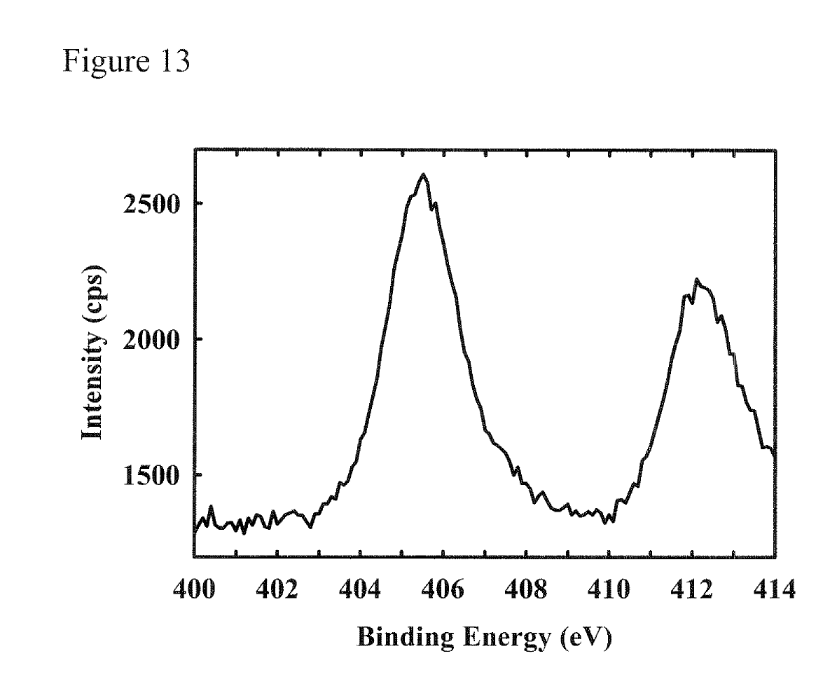

XPS spectra of patterned planar substrates are reported in FIG. 13. Two Cd peaks were clearly evident, with binding energies of: Cd_{3d5/2=}405.5 eV, and Cd_{3d3/2=}412.2 eV; the sulfur peak had a maximum around 162.5 eV, which corresponded to S_{2p3/2}, and a shoulder around 163.5 eV, which corresponded to S_{2p1/2}. All these values are in excellent agreement with those previously reported for CdS nanoparticles capped with mercaptoethanol by M. Kundu, A. A. Khosravi, S. K. Kulkarni and P. Singh, J. Mater. Sci., 1997, 32, 245 and R. B. Khomane, A. Manna, A. B. Mandale and B. D. Kulkarni, Langmuir, 2002, 18, 9237. The precursor solution had a CdSO₄ concentration of 0.1 M and a RSH concentration of 1 M. The samples were illuminated for 60 minutes with a 100 W Hg lamp.

### Example 6

### CdS Nanoparticles on a Silica Hydrogel using IR Radiation and Capping Agents

Silica hydrogels were prepared mixing the contents of vial A (4.514 mL of tetramethoxysilane; 3.839 mL of methanol) and of vial B (4.514 mL of methanol; 1.514 mL of water, and 20 μL of concentrated NH₄OH) to form a sol that gels at room temperature in 10-15 min. The gels were left to age at room temperature for approximately 2 days. Aged gels were removed from their molds and soaked in methanol, four times, for 12 hours each time. The hydrogels were then soaked in water, four times, for 12 h each time. The water-washed gels were then cut into cylinders of about 7 mm diameter, and 4-5 mm length, and placed in 20 ml of precursor solution.

Each hydrogel slice was soaked in a precursor solution consisting of CdNO₃ (1 mol/l) and NH₄OH (4 mol/l). The samples were then placed in a refrigerator kept at 50° C. After about two hours, half of the bathing solution was decanted and replaced with an aqueous solution containing thiourea with a concentration of 1 mol/l, and a capping agent. As capping agents, 2-mercaptoethanol, thioglycerol, and sodium hexametaphosphate (HMP, average molecular weight=611.7) were used. Their concentration was varied between 0.01 and 0.1 mol/l. The samples were left in the refrigerator for an additional hour to let thiourea diffuse inside the monoliths. Cooling was necessary, since the precursors react, albeit slowly, at room temperature. Hydrogels loaded with the precursors turned pale yellow within about one hour when kept at room temperature, but did not change appreciably their color when refrigerated. The samples were then rapidly removed from the refrigerator, placed in a glass cuvette, and exposed to the light of a continuous wave, Nd-YAG laser. Samples were exposed to the IR beam for between 4 and 10 minutes, and the estimated power on the sample was about 1.8 W. After exposure, the samples were immediately washed several times in cold distilled water to quench any further reaction of the precursors. For bulk (three-dimensional) patterning, an IPG Photonics corporation laser of model number YLR-100 which is a continuous-wave laser was employed, emitting at a wavelength of 1065 nm, and with a power of 23 W. The laser beam was focused 6 mm below the surface of a hydrogel monolith with a lens of focal length 5 cm.

Samples were characterized with transmission electron microscopy (TEM, and high resolution TEM), with UV-Vis optical absorption spectroscopy, photoluminescence spectroscopy, X-ray diffraction (XRD), and X-ray photoelectron spectroscopy (XPS).

The apparatus used were a Zeiss EM 109, operated at 80 kV and Phillips 430ST TEM, operated at 300 kV, a CARY 5 UV-Vis-NIR spectrophotometer, a JY-Horiba Fluorolog 3-22 Fluorometer, a Scintag XDS200 diffractometer with a Cu radiation source and a liquid nitrogen cooled Ge detector, and a KRATOS AXIS 165 scanning spectrometer equipped with a 225-W Mg monochromatized X-ray source, producing photons with an average energy of 1253.6 eV respectively.

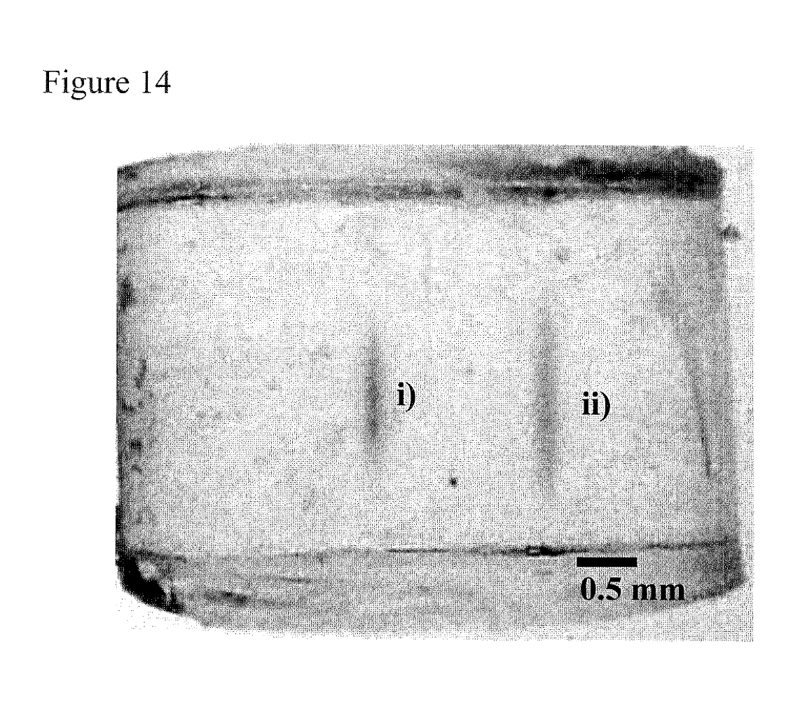

The patterned regions had a yellow color, and were clearly distinguishable from the matrix. The patterned regions in FIG. 14 had a size between 1 and 3 mm to facilitate digital camera imaging; however, we were able to fabricate patterns as small as 40 mm. After irradiation, the samples were washed several times in water to remove unreacted precursors. The size and color of the spots did not change after washing, indicating that CdS was neither chemically altered nor removed by the washings. To help confirming the chemical identity of the nanoparticles in the illuminated regions, some samples were placed in acidic (H₂SO₄) solution. The lithographed regions vanished after a few hours, ruling out the presence of elemental sulfur, and strongly suggesting the presence of CdS nanoparticles.

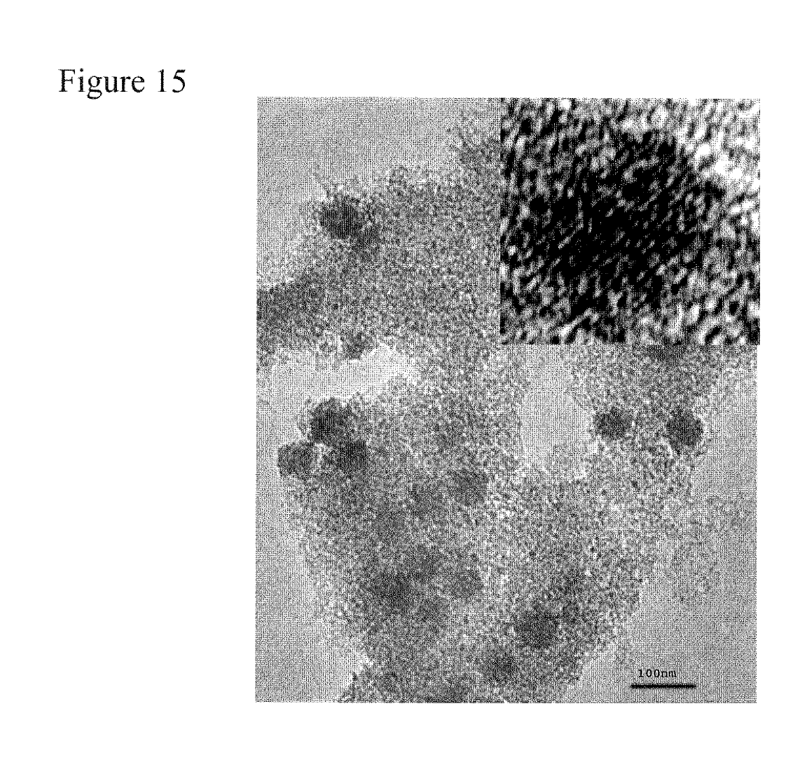

For TEM analysis, illuminated regions were carved out of the hydrogel, crushed in methanol and placed on a lacey carbon copper grid. FIG. 15 shows a typical TEM micrograph. CdS nanoparticles with diameter in the 15-25 nm range were present in all samples, and appeared as dark spots distributed within the light grey silica hydrogel. High magnification micrographs revealed the presence of a large number of smaller particles, whose lattice fringes could be occasionally detected, as shown in the inset of FIG. 15.

Samples were additionally characterized with optical techniques, which included absorption, photoluminescence, and Raman spectroscopy.

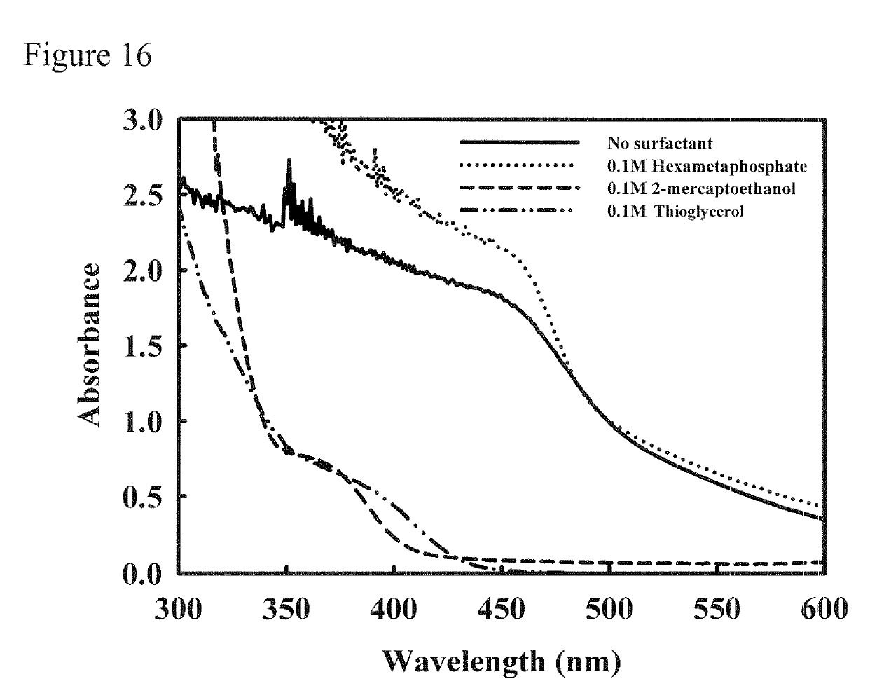

Room temperature absorption spectra of samples containing different capping agents are reported in FIG. 16. When capping agents were not added to the solution, the spectra exhibited an excitonic shoulder around 460 nm, which corresponded to a mean particle size of about 4.5 nm. Addition of HMP did not affect strongly the particle size, the absorption spectra continued to exhibit an excitonic shoulder around 460 nm. Addition of thiols shifted the excitonic shoulder towards higher energies. The excitonic shoulder was around 370 nm for 2-mercaptoethanol, and around 380 nm for thioglycerol. The mean particle size, estimated from the position of the excitonic shoulder, was about 2 nm (2-mercaptoethanol) and about 2.5 nm (thioglycerol). Variation of the thiol concentration between 0.01 and 0.1 mol/l did not strongly affect the position of the excitonic shoulder. For capping agent concentrations higher than about 0.1 M, CdS nanoparticles did not form, independent of the capping agent.

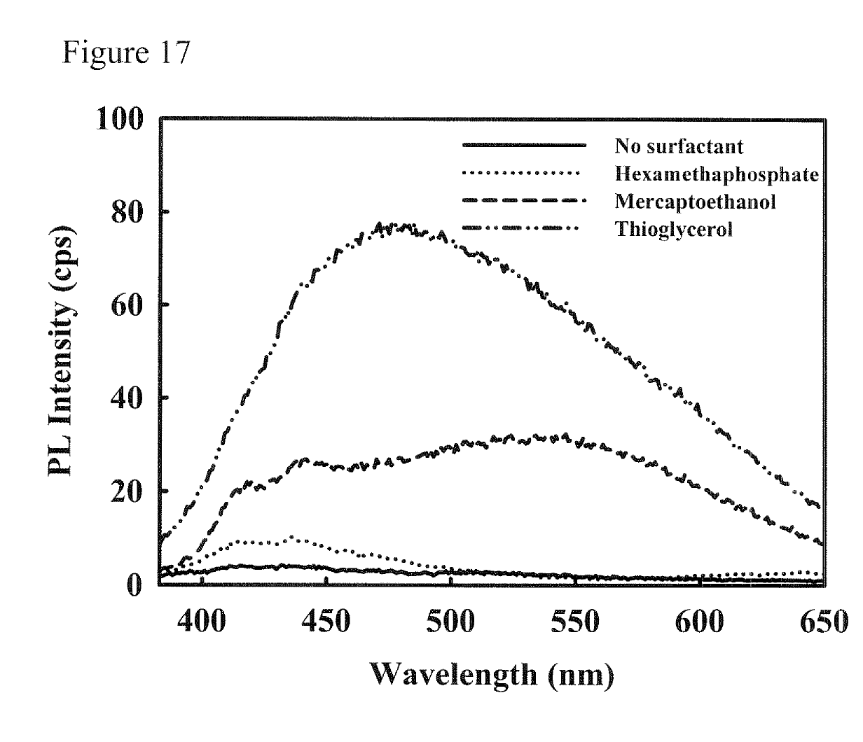

Room temperature photoluminescence (PL) spectra are reported in FIG. 17, and are characterized by broad peaks, indicating that the nanoparticles had a substantial number of defects. Particle size could not be determined from the PL spectra due to the broadness of the peaks; however, some trends could be discerned. Luminescence was in general weak. Peaks in the 400-450 nm region of the spectrum were often detected, and were probably due to carbon impurities incorporated in the silica matrix during gel synthesis. The luminescence intensity increased in samples capped with thiols, and increased with the length of the aliphatic chain.

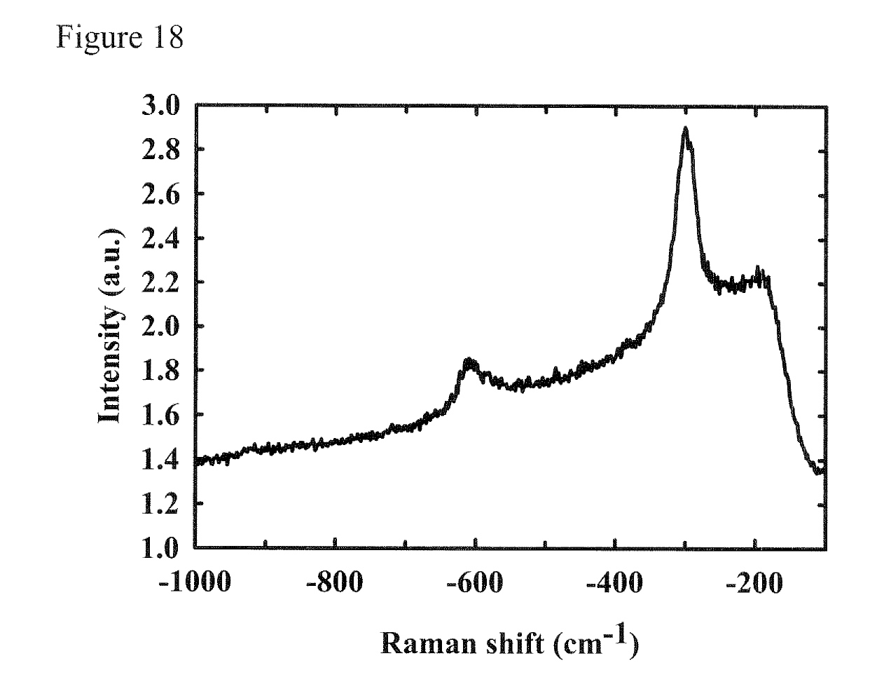

Raman spectra are shown in FIG. 18, and exhibited a shift at 300 cm⁻¹. This frequency corresponded to the first-order LO phonon frequency of CdS. A peak at 600 cm⁻¹ was also routinely observed, which corresponded to the first overtone.

### Example 7

### CdS Nanoparticles on a Planar Substrate using IR Radiation

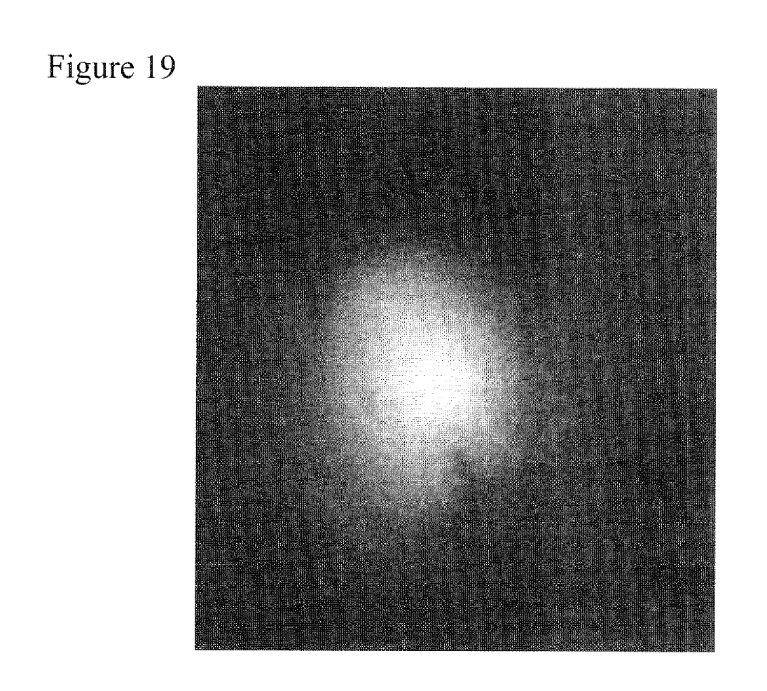

A thin veil of precursor solution including CdNO₃ (0.5 mol/l), NH₄OH (2 mol/l), and thiourea (0.5 mol/l), was spin coated, or simply spread, on glass slides or silicon wafers. The samples were exposed to focused infrared light as shown in FIG. 1B, yellow spots formed in the illuminated regions after an exposure of about 3 minutes, as shown in FIG. 19. the samples were then immediately washed with cold water to remove unreacted precursors.

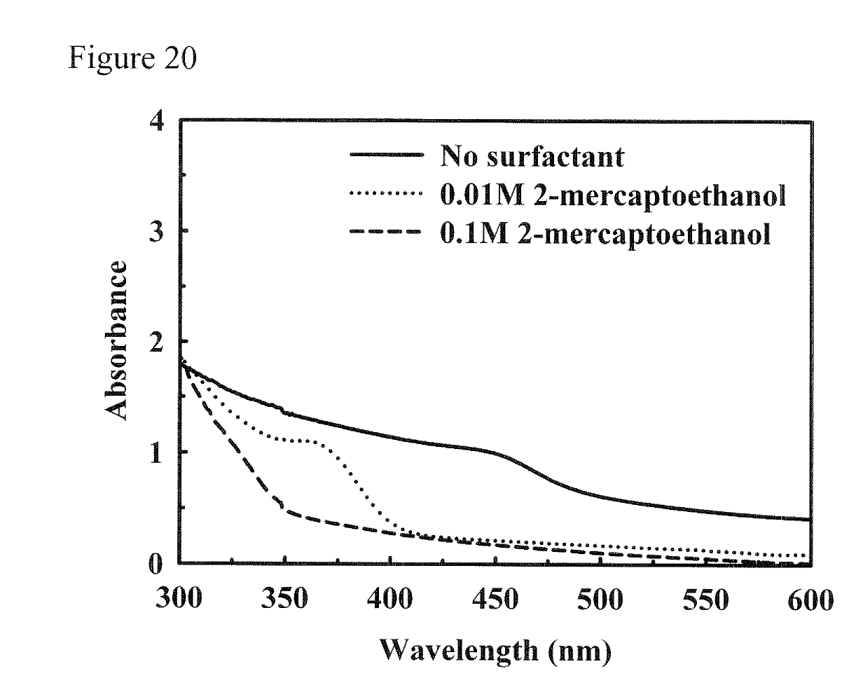

FIG. 20 shows the absorption spectra of glass slides patterned with CdS as a function of the concentration of 2-mercaptoethanol. Excitonic shoulders were detected in all samples and were located at about 440 nm in samples without capping agents, around 370 nm in samples with [2-mercaptoethanol]=0.01 M, and around 325 nm in samples with [2-mercaptoethanol]=0.1 M. These values of the excitonic absorption corresponded to mean particle sizes of 2.6, 1.7, and 1.2 nm respectively. Optical absorption therefore indicates that quantum-confined particles formed even without addition of a surfactant. Addition of 2-mercaptoethanol to the precursor solution had a more strong effect than in photopatterning of porous matrices.

These mean particle sizes are comparable to the values obtained for porous matrices and show that the capping agent was more efficient than the matrix pores in limiting particle size.

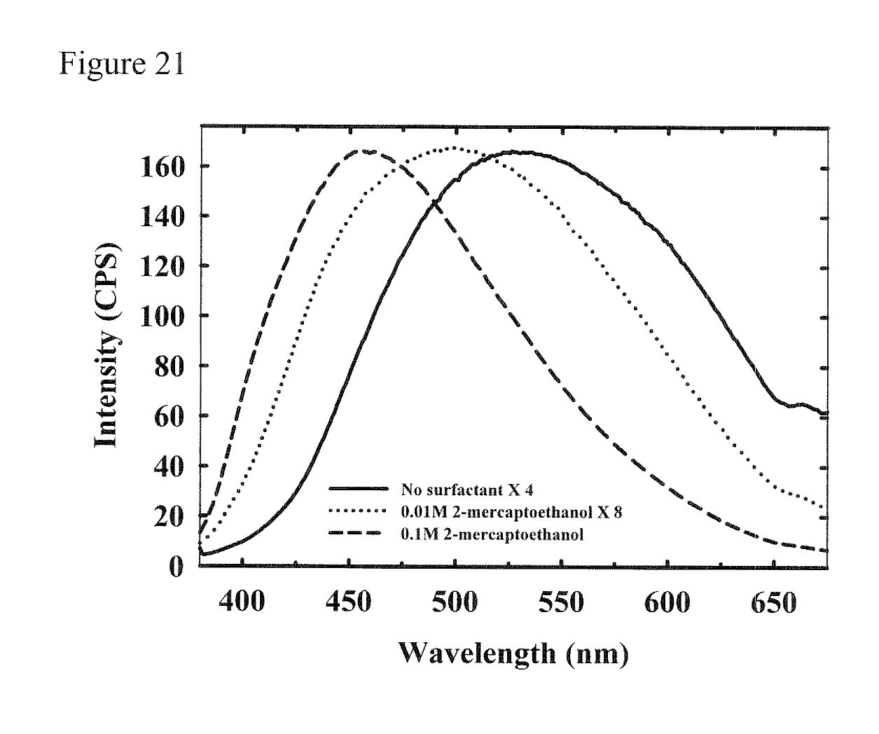

Photoluminescence spectra are also reported in FIG. 21. Samples without capping agents had a weak, broad emission spectrum, similar to that of CdS powders, which indicated a polydispersity and a large number of defects. Emission shifted towards higher energies and became narrower with increasing capping agent concentration. The shift towards higher energies of the emission is consistent with the blue shift of the absorption and the reduction in particle size.

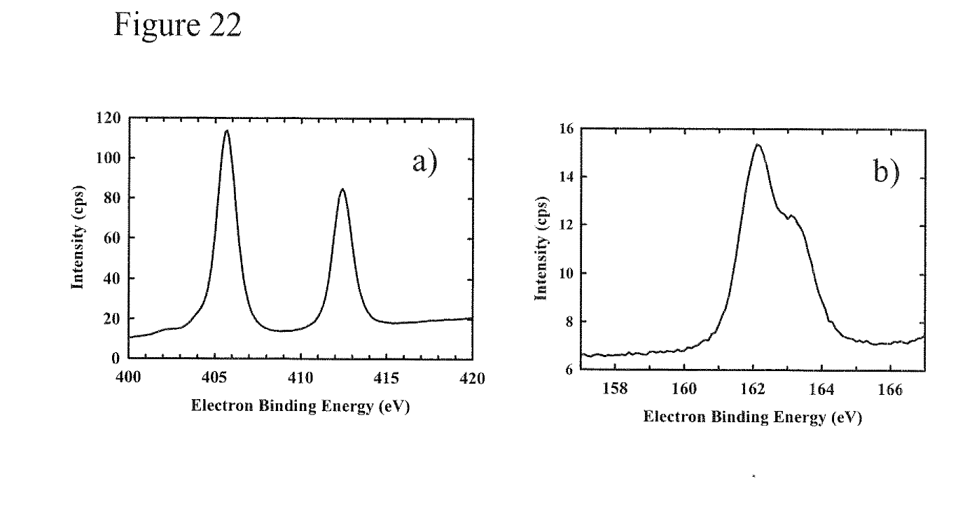

XPS spectra of patterned silicon wafers are reported in FIG. 22. Two Cd peaks were clearly evident, with binding energies of Cd_{3d5/2}=405.6 eV, and Cd_{3d3/2}=412.2 eV; the sulfur peak had a maximum around 162.0 eV, which corresponded to S_{2p3/2}, and a shoulder around 163.2 eV, which corresponded to S_{2p1/2}. All these values are in excellent agreement with those previously reported for CdS nanoparticles by M. Kundu, A. A. Khosravi, S. K. Kulkarni and P. Singh, J. Mater. Sci., 1997, 32, 245 and R. B. Khomane, A. Manna, A. B. Mandale and B. D. Kulkarni, Langmuir, 2002, 18, 9237, and further confirm the chemical identity of the nanoparticles.

What is claimed is:

1. A process for forming a metal-containing nanoparticle on or in a substrate, the process comprising:
(a) contacting the substrate with a solution to form a substrate solution mixture, the solution comprising a metallic agent and a second agent; and,
(b) applying a directional radiation source to the substrate solution mixture, the directional radiation source causing the second agent to dissociate into at least two particles initiating a reaction between the metallic agent and the dissociated second agent such that the metallic agent deposits on or in the substrate forming a metal-containing nanoparticle.

2. The process of claim 1, wherein the substrate is a porous matrix selected from the group consisting of a hydrogel, a zeolite, an aerogel, a xerogel, an ambigel, a ceramic, a silicon wafer, and a quartz, a glass, and a polymer.

3. The process of claim 1, wherein the substrate is a planar substrate selected from the group consisting of a glass, a silicon wafer, and a quartz.

4. The process of claim 1, wherein the metallic agent is a metal ion selected from the group consisting of silver, gold, cadmium, lead, and mercury.

5. The process of claim 1, wherein the metallic agent is a metal complex selected from the group consisting of silver nitrate, cadmium nitrate, cadmium sulfate, silver sulfate, lead nitrate, and zinc nitrate.

6. The process of claim 1, wherein the second agent is a reducing agent selected from the group consisting of formaldehyde, hydrazine, sodium borohydride, and ferrous compounds.

7. The process of claim 1, wherein the second agent is a sulfur-containing agent selected from the group consisting of 2-mercaptoethanol, thioglycerol, thiourea, thioacetamide, and mercaptoundecanol.

8. The process of claim 1, wherein the directional radiation source is continuous or pulsed.

9. The process of claim 8, wherein the directional radiation source is ionizing radiation selected from the group consisting of ultraviolet light, gamma rays, and X-rays.

10. The process of claim 8, wherein the directional radiation source is non-ionizing radiation is selected from the group consisting of infrared light, visible light, and microwaves.

11. The process of claim 1, further comprising:
(a) contacting the metal-containing nanoparticle substrate with a second solution to form a second substrate solution mixture, the second solution comprising a second metallic agent and a third agent;
(b) applying a directional radiation source to the second substrate solution mixture, the directional radiation source initiating a reaction between the second metallic agent and the third agent such that the metallic agent deposits on or in the metal-containing nanoparticle substrate forming a second metal-containing nanoparticle on or in the metal-containing nanoparticle substrate.

12. The process of claim 11, wherein the metallic agent and second metallic agent are the same.

13. The process of claim 11, wherein the metallic agent is not the same as the second metallic agent.

14. A non-etched, porous substrate, the substrate having selectively patterned metal-containing nanoparticles deposited on or in the substrate, the metal-containing nanoparticles comprising a metal ion selected from the group of consisting of cadmium, mercury, copper, palladium, platinum, lead, and zinc.

15. The substrate of claim 14, wherein the substrate is a porous matrix selected from the group consisting of a hydrogel, a zeolite, an aerogel, a xerogel, an ambigel, a ceramic, and a polymer.

16. The substrate of claim 14, wherein the metal-containing nanoparticles have an average diameter from about 1 nanometer to about 10 nanometers and wherein the density of metal-containing nanoparticles on the substrate is from about 0.001% to about 30% (v/v).

17. The substrate of claim 14, wherein the metal-containing nanoparticles are quantum dots made of a material selected from the group consisting of cadmium sulfide, zinc sulfide, lead sulfide, cadmium selenide, cadmium telluride, zinc selenide, zinc telluride, lead selenide, zinc selenide, and mercury telluride.

18. The substrate of claim 14, wherein the metal-containing nanoparticles are deposited on or in the substrate in a two-dimensional pattern or in a three-dimensional pattern.

19. A non-etched, planar substrate, the planar substrate having selectively patterned metal-containing nanoparticles deposited on the substrate's surface.

20. The substrate of claim 19, wherein the substrate is selected from the group consisting of a glass, a silicon wafer, and a quartz.

21. The substrate of claim 19, wherein the metal-containing nanoparticles are deposited on the substrate in a two-dimensional pattern.
